(19) United States
(12) Patent Application Publication
(10) Pub. No.: US 2018/0145236 A1
(43) Pub. Date: May 24, 2018

(54) PACKAGE STRUCTURE FOR LIGHT EMITTING DEVICE

(71) Applicant: Industrial Technology Research Institute, Hsinchu (TW)

(72) Inventors: Yu-Wei Huang, Chiayi City (TW); Tao-Chih Chang, Taoyuan City (TW); Chih-Ming Shen, New Taipei City (TW)

(73) Assignee: Industrial Technology Research Institute, Hsinchu (TW)

(21) Appl. No.: 15/857,628

(22) Filed: Dec. 29, 2017

Related U.S. Application Data
(63) Continuation of application No. 14/952,919, filed on Nov. 26, 2015.
(60) Provisional application No. 62/087,807, filed on Dec. 5, 2014.
(60) Provisional application No. 62/087,808, filed on Dec. 5, 2014.
(60) Provisional application No. 62/095,726, filed on Dec. 22, 2014.
(60) Provisional application No. 62/100,075, filed on Jan. 6, 2015.

(30) Foreign Application Priority Data
Jun. 30, 2015 (TW) 104121269

(51) Int. Cl. H01L 33/62; H01L 25/075; H01L 21/56; H01L 33/58

(52) U.S. Cl. CPC H01L 33/62; H01L 2224/18; H01L 25/0756; H01L 2224/73267; H01L 2224/73204; H01L 2224/32225; H01L 2224/24137; H01L 21/568; H01L 2224/16225; H01L 2224/12105; H01L 2224/04105; H01L 33/58; H01L 2224/92244; H01L 2924/18162; H01L 25/0753

(57) ABSTRACT

A package structure for a light emitting device including a carrier, a plurality of package units, an interconnection structure is provided. The carrier has a carrying surface, the package units stack on the carrying surface, each of the package units has a first surface and a second surface opposite the first surface and a plurality of light emitting devices arranged in an array and embedded in the package unit. Each of the light emitting devices includes a top portion facing the carrier, a bottom portion opposite to the top portion and a first electrode on the top portion, the bottom portion of each of the plurality of light emitting devices is coplanar with the first surface of the package unit. The interconnection structure is located in the package units and includes a plurality of conductive vias passing through the corresponding package units and electrically connected between the corresponding first electrodes.

### CROSS-REFERENCE TO RELATED APPLICATION

This is a continuation application of and claims the priority benefit of U.S. application Ser. No. 14/952,919, filed on Nov. 26, 2015, now pending, which claims the priority benefits of U.S. provisional application Ser. No. 62/087,807, filed on Dec. 5, 2014, U.S. provisional application Ser. No. 62/087,808, filed on Dec. 5, 2014, U.S. provisional application Ser. No. 62/095,726, filed on Dec. 22, 2014, U.S. provisional application Ser. No. 62/100,075, filed on Jan. 6, 2015, and Taiwan application serial no. 104121269, filed on Jun. 30, 2015. The entirety of each of the above-mentioned patent applications is hereby incorporated by reference herein and made a part of this specification.

### TECHNICAL FIELD

The present invention generally relates to a package structure, and particularly to a package structure for a light emitting device.

### BACKGROUND

With the development of electro-optics technology, electro-optics devices go towards miniaturization. Recently, a variety of micro-display techniques are proposed, including micro-LED displays and OLED displays both adopting display technique of active light emitting devices. In particular, the micro-LED displays have not only high contrast ratio and low power consumption as the OLED displays but also high reliability and long lifetime, and likely become the mainstream of display techniques in mobile communications or wearable electronics for Internet of Things (IoT).

### SUMMARY

The disclosure provides a package structure for a light emitting device, wherein an anisotropic conductive film (ACF) and flip-chip bonding technique are applied for bonding the light emitting device to a carrier, to accomplish low temperature and fine-pitch package process, which is simple, quick and suitable for mass production.

The package structure of the disclosure includes a carrier, plural package units and an interconnection structure. The carrier has a carrying surface. The package units are sequentially stacked on the carrying surface, and each of the package units includes an encapsulant, plural light emitting devices and plural conductive bumps. Each encapsulant has a first surface and a second surface opposite to the first surface, wherein the second surface of an upper encapsulant is bonded to the first surface of a lower encapsulant of another package unit. The light emitting devices are arranged in an array and embedded in the first surfaces of the encapsulants. Each of the light emitting devices comprises a top portion facing the carrier, a bottom portion opposite to the top portion and a first electrode on the top portion, and the bottom portion of each of the light emitting devices is coplanar with the first surface of the corresponding encapsulant. The conductive bumps are embedded in the second surfaces of the encapsulants. The interconnection structure is located in the encapsulants of the package units, and the interconnection structure comprises plural first circuit layers and plural conductive vias. The first circuit layers are disposed between two adjacent encapsulants or between the carrier and the encapsulant adjacent to the carrier, and electrically connected to the corresponding light emitting devices through the conductive bumps. The conductive vias pass through the corresponding encapsulants and electrically connected between the corresponding first circuit layers.

The disclosure provides another package structure capable of accomplishing full-color display, wherein package units having light emitting device arrays are formed by flip-chip bonding technique before laminating the package units together to form the package structure. For example, the package units having light emitting devices in different colors such as red, green and blue, are stacked with one another to form a full-color display. Each package unit has an interconnection structure itself, and the package units are electrically connected with one another through their interconnection structures. The package structure of the disclosure provides simple and quick manufacturing process and is suitable for mass production. Furthermore, solutions for optical issues such as light guiding or light mixing are also provided.

To make the above features and advantages of the disclosure more comprehensible, embodiments accompanied with drawings are described in detail below.

### BRIEF DESCRIPTION OF THE DRAWINGS

FIG. 1 illustrates a package structure of a light emitting device according to an embodiment of the present disclosure.

FIG. 2A through FIG. 2D illustrate a package process of the package structure of FIG. 1.

FIG. 3 illustrates a package structure of a light emitting device according to an embodiment of the present disclosure.

FIG. 4 illustrates a package structure of a light emitting device according to an embodiment of the present disclosure.

FIG. 5 illustrates a package structure of a light emitting device according to an embodiment of the present disclosure.

FIG. 6A through FIG. 6H illustrates a package process of a light emitting device according to an embodiment of the present disclosure.

FIG. 7 illustrates performing a singulation process to a wafer to form strip-type light emitting units according to an embodiment of the present disclosure.

FIG. 8 illustrates a package structure of a light emitting device capable of accomplishing full-color display according to an embodiment of the present disclosure.

FIG. 9A through FIG. 9C respectively shows vertical projections of the package structure of FIG. 8 on a plane.

FIG. 10 illustrates a package structure of a light emitting device according to an embodiment of the present disclosure.

FIG. 11 illustrates a package structure of a light emitting device according to an embodiment of the present disclosure.

FIG. 12 illustrates a package structure of a light emitting device according to an embodiment of the present disclosure.

FIG. 13 illustrates a package structure of a light emitting device according to an embodiment of the present disclosure.

FIG. 14 illustrates a package structure of a light emitting device according to an embodiment of the present disclosure.

FIG. 15 is a partial view of a package structure of a light emitting device according to an embodiment of the present disclosure.

FIG. 16 illustrates a package structure of a light emitting device according to an embodiment of the present disclosure.

FIG. 17 illustrates a package structure of a light emitting device according to an embodiment of the present disclosure.

FIG. 18 illustrates a package structure of a light emitting device according to an embodiment of the present disclosure.

FIG. 19 illustrates a package structure of a light emitting device according to an embodiment of the present disclosure.

FIG. 20 illustrates a package structure of a light emitting device according to an embodiment of the present disclosure.

FIG. 21 illustrates a package structure of a light emitting device according to an embodiment of the present disclosure.

FIG. 22 illustrates a package structure of a light emitting device capable of accomplishing full-color display according to an embodiment of the present disclosure.

FIG. 23A through FIG. 23G illustrate a package process of the package structure of FIG. 22.

FIG. 24A through FIG. 24C respectively shows vertical projections of the package structure of FIG. 22 on a plane.

FIG. 25 illustrates a package structure of a light emitting device according to an embodiment of the present disclosure.

FIG. 26 illustrates a package structure of a light emitting device according to an embodiment of the present disclosure.

FIG. 27 illustrates a package structure of a light emitting device according to an embodiment of the present disclosure.

FIG. 28 illustrates a package structure of a light emitting device according to an embodiment of the present disclosure.

FIG. 29 illustrates a package structure of a light emitting device according to an embodiment of the present disclosure.

FIG. 30 illustrates a package structure of a light emitting device according to an embodiment of the present disclosure.

FIG. 31 illustrates a package structure of a light emitting device according to an embodiment of the present disclosure.

FIG. 32 illustrates a package structure of a light emitting device according to an embodiment of the present disclosure.

FIG. 33 illustrates a package structure of a light emitting device capable of accomplishing full-color display according to an embodiment of the present disclosure.

FIG. 34A through FIG. 34G illustrate a package process of the package structure of FIG. 33.

FIG. 35A through FIG. 35C respectively shows vertical projections of the package structure of FIG. 33 on a plane.

FIG. 36 illustrates a package structure of a light emitting device according to an embodiment of the present disclosure.

FIG. 37 illustrates a package structure of a light emitting device according to an embodiment of the present disclosure.

FIG. 38 illustrates a package structure of a light emitting device according to an embodiment of the present disclosure.

FIG. 39 illustrates a package structure of a light emitting device according to an embodiment of the present disclosure.

FIG. 40 illustrates a package structure of a light emitting device according to an embodiment of the present disclosure.

FIG. 41 illustrates a package structure of a light emitting device according to an embodiment of the present disclosure.

FIG. 42 illustrates a package structure of a light emitting device according to an embodiment of the present disclosure.

FIG. 43 illustrates a package structure of a light emitting device according to an embodiment of the present disclosure.

FIG. 44 illustrates a package structure of a light emitting device according to an embodiment of the present disclosure.

FIG. 45 illustrates a package structure of a light emitting device according to an embodiment of the present disclosure.

### DETAILED DESCRIPTION OF DISCLOSED EMBODIMENTS

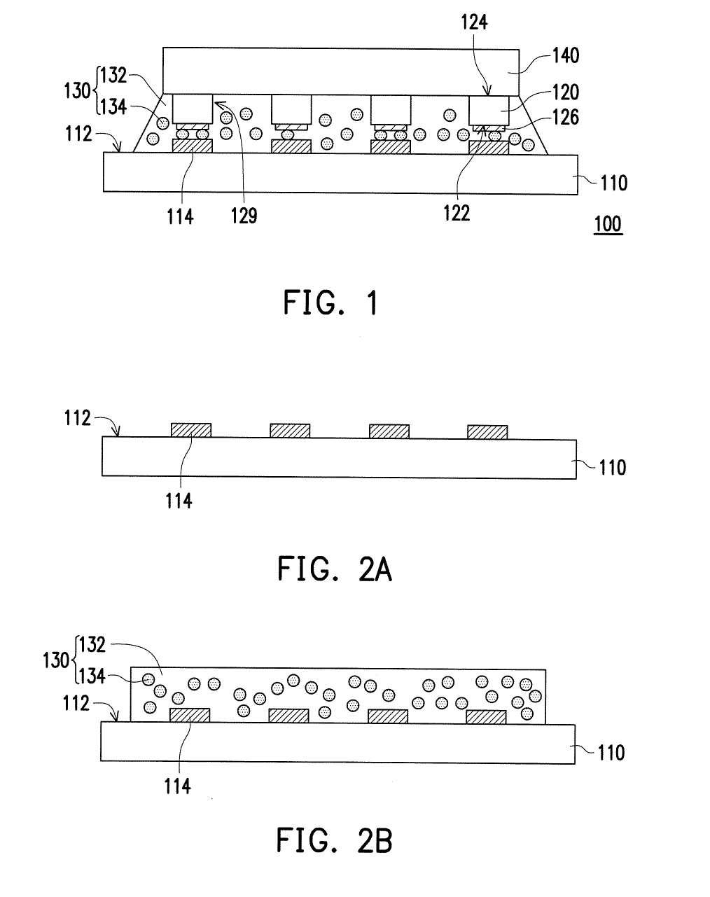

FIG. 1 illustrates a package structure 100 of a light emitting device according to an embodiment of the present disclosure. In the present embodiment, an anisotropic conductive film and flip-chip bonding technique are applied for bonding the light emitting device to a carrier, to accomplish low temperature and fine-pitch package process, which is simple, quick and suitable for mass production.

As shown in FIG. 1, the package structure 100 includes a carrier 110, plural light emitting devices 120 and an anisotropic conductive film 130. The carrier 110 has a carrying surface 112 and a plurality of electrode contacts 114 on the carrying surface 112. Herein, the carrier 110 may be a semiconductor substrate, a glass substrate, a circuit substrate or other applicable substrates, wherein the semiconductor substrate is for example a drive IC including electronic circuitry.

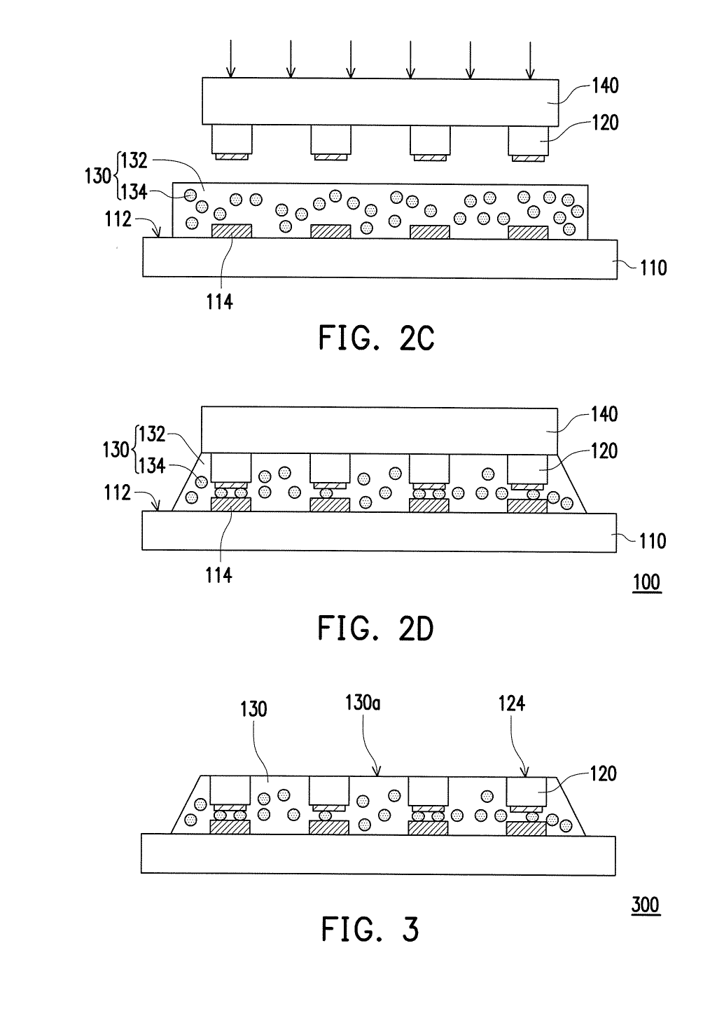

The light emitting devices 120 are arranged in an array and disposed on the carrying surface 112. In the present embodiment, the light emitting devices 120 are light emitting diodes (LEDs), for example. In process, as shown in FIG. 2A, a carrier 110 having electrode contacts 114 can be provided. Then, as shown in FIG. 2B, the anisotropic conductive film 130 covering the electrode contacts 114 is attached to the carrying surface 112 of the carrier 110 after the carrying surface 112 is cleaned. In addition, plural light emitting devices 120 are formed on the epitaxial substrate 140, wherein a pitch between two adjacent light emitting devices 120 is for example less than 50 μm. Next, referring to FIG. 2C, the epitaxial substrate 140 with the light emitting devices 120 thereon is bonded to the electrode contacts 114 on the carrier 110 through flip-chip bonding technique. Then, the package structure 100 as shown in FIG. 2D is formed.

Here, in consideration of warpage or low reliability caused by thermal stress between devices due to large difference of coefficient of thermal expansion when bonding the light emitting devices 120 to the electrode contacts 114 through a conventional solder paste, the anisotropic conductive film 130 is adopted, instead of the solder paste, to connect the light emitting devices 120 with the corresponding electrode contacts 114.

More specifically, as shown in FIG. 1, each of the light emitting devices 120 includes a top portion 122 facing the carrier 110, a bottom portion 124 opposite to the top portion 122 and a first electrode 126 on the top portion 122. The anisotropic conductive film 130 is disposed on the carrying surface 112 and at least covering the electrode contacts 114, the top portion 122 and the first electrode 126 of each of the light emitting devices 120, and a portion of a side surface 129 of each of the light emitting devices 120. In the present embodiment, the anisotropic conductive film 130 fills the space between the carrier 110 and the epitaxial substrate 140. In other words, the anisotropic conductive film 130 covers the entire side surface 129 of each of the light emitting devices 120. It is noted that, without specific description, the light emitting devices 120 of the present embodiment or the following embodiments may be vertical-type LED or horizontal-type LED. In other words, besides the first electrode 126 on the top portion 122, the light emitting device 120 in vertical structure may further comprise a second electrode on its bottom portion 124, while the light emitting device 120 in horizontal structure may further comprise a second electrode on its top portion 122. In order to clearly illustrate some specific features, the second electrode may be omitted in figures of some embodiments. However, one of ordinary skill in the art can still realize or determine location of the second electrode from other embodiments.

Furthermore, the aforementioned epitaxial substrate 140 or the epitaxial substrates in the following embodiments may be replaced by other types of substrates. For example, light emitting diodes may be transferred to a silicon substrate or other substrates after being fabricated from the epitaxial substrate, and then a following process, such as package process, is conducted.

The anisotropic conductive film 130 includes an insulation body 132 and a plurality of conductive particles 134 in the insulation body 132, and the first electrode 126 of each of the light emitting devices 120 is electrically connected to the corresponding electrode contact 114 through the conductive particles 134. Herein, the insulation body 132 may be thermosetting polymer or thermoplastic polymer. The conductive particles 134 are capable of compensating the variation of gap between the light emitting device 120 and its corresponding electrode contacts 114 due to warpage caused by thermal stress between the carrier 110 and the epitaxial substrate 140. In addition, by using the anisotropic conductive film 130, process temperature of the package structure 100 of the present embodiment is low (e.g. lower than 200° C.), and the package structure 100 is compatible for fine-pitch process. A wafer level package can be accomplished without addition step for forming underfill, wherein all of the light emitting devices 120 on the epitaxial substrate 140 can be bonded to the carrier through a single bonding step, and thus the process is simple, quick and suitable for mass production. Furthermore, the conventional solder paste for bonding process is not required, and thus use of material of lead and halogen in process can be prevented for environmental protection.

FIG. 3 illustrates a package structure 300 of a light emitting device according to an embodiment of the present disclosure. A package structure 300 according to the present embodiment is partially similar to the package structure 100 according to the previous embodiment, except that the package structure 300 is provided without epitaxial substrate 140. To facilitate description, in the following embodiments of the disclosure, the same or similar devices are denoted by similar reference numerals as those in the previous embodiments. Some devices illustrated in the previous embodiments may be omitted, and descriptions of those omitted devices can be referred to the previous embodiments, and are not repeated herein.

More specifically, as shown in FIG. 3, the epitaxial substrate 140 in the previous embodiment is removed by such as laser, mechanical grinding or chemical treatment after the package process to meet the requirement of heat dissipation, optical modulation or minimization. Therefore, the bottom portion 124 of the light emitting devices of the present embodiment are coplanar with the first surface 130a of the anisotropic conductive film 130, and the anisotropic conductive film 130 exposes the bottom portion 124 of each of the light emitting devices 120.

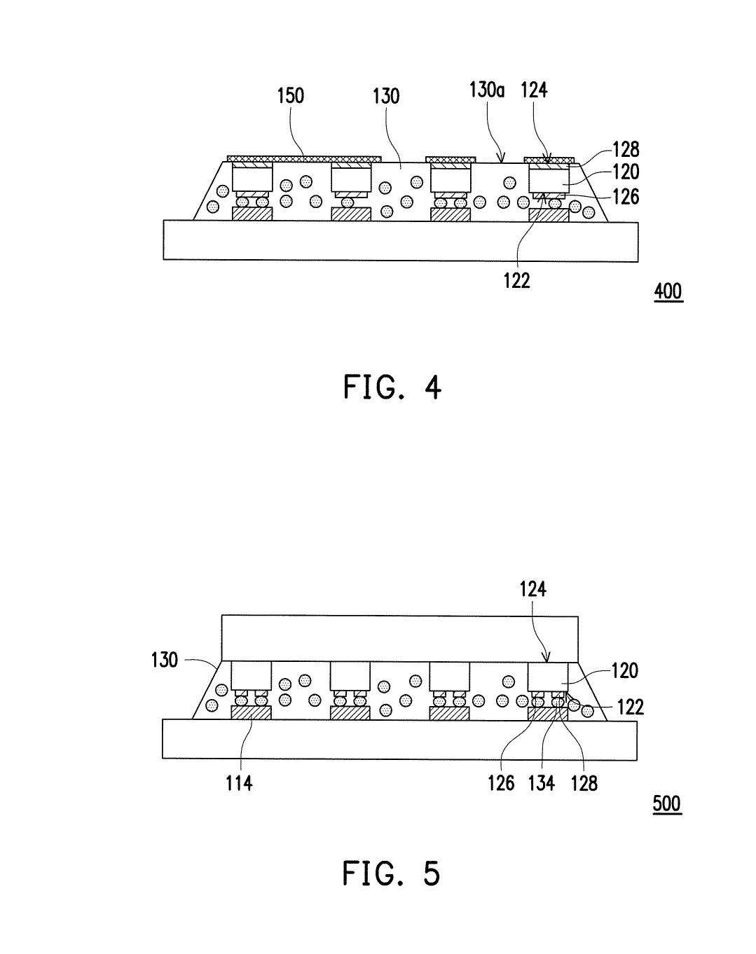

FIG. 4 illustrates a package structure 400 of a light emitting device according to an embodiment of the present disclosure. In the present embodiment, the same or similar devices are denoted by similar reference numerals as those in the previous embodiments. Some devices illustrated in the previous embodiments may be omitted, and descriptions of those omitted devices can be referred to the previous embodiments. Main difference between the present embodiment and the previous embodiment is illustrated below.

In the present embodiment, the light emitting devices 120 are vertical-type LEDs, for example. Each light emitting device 120 includes a second electrode 128 on its bottom portion 124 besides the first electrode 126 on the top portion 122, wherein the first electrode 126 may be a P-type electrode of LED, and the second electrode 128 may be an N-type electrode of LED. The second electrodes 128 of the present embodiment can be connected to form a common N-type electrode. Therefore, a circuit layer 150 can be formed on the first surface 130a of the anisotropic conductive film 130 after the epitaxial substrate 140 of the previous embodiment is removed. Herein, the circuit layer 150 may be formed of metal such as gold, copper, aluminum, chromium, titanium, etc., or may be a transparent conductive layer formed of oxide of metals such as indium tin oxide (ITO) or indium zinc oxide (IZO). Herein, the second electrodes 128 can be replaced by a conductive layer, for example a transparent conductive layer formed of ITO or IZO, covering the entire first surface 130a, or a circuitry or electrodes formed by patterning a conductive layer.

FIG. 5 illustrates a package structure 500 of a light emitting device according to an embodiment of the present disclosure. A package structure 500 according to the present embodiment is partially similar to the package structure 100 according to the previous embodiment, except that the light emitting devices 120 of the package structure 500 are horizontal-type LEDs. To facilitate description, in the following embodiments of the disclosure, the same or similar devices are denoted by similar reference numerals as those in the previous embodiments. Some devices illustrated in the previous embodiments may be omitted, and descriptions of those omitted devices can be referred to the previous embodiments, and are not repeated herein.

As shown in FIG. 5, each of the light emitting devices 120 of the present embodiment has a firs electrode 126 and a second electrode 128 on its top portion 122, and the first electrode 126 and the second electrode 128 are respectively and electrically connected to their corresponding electrode contacts 114 through the anisotropic conductive film 130.

In the previous embodiments, the light emitting devices 120 are LEDs fabricated on the same epitaxial substrate 140, and thus emit lights in the same color. However, the disclosure is not limited thereto. In other embodiment, the light emitting devices 120 may include first color (e.g. red) LEDs, second color (e.g. green) LEDs, or third color (e.g. blue) LEDs, or even fourth color or more color LEDs. Some embodiments of package process are illustrated hereinafter.

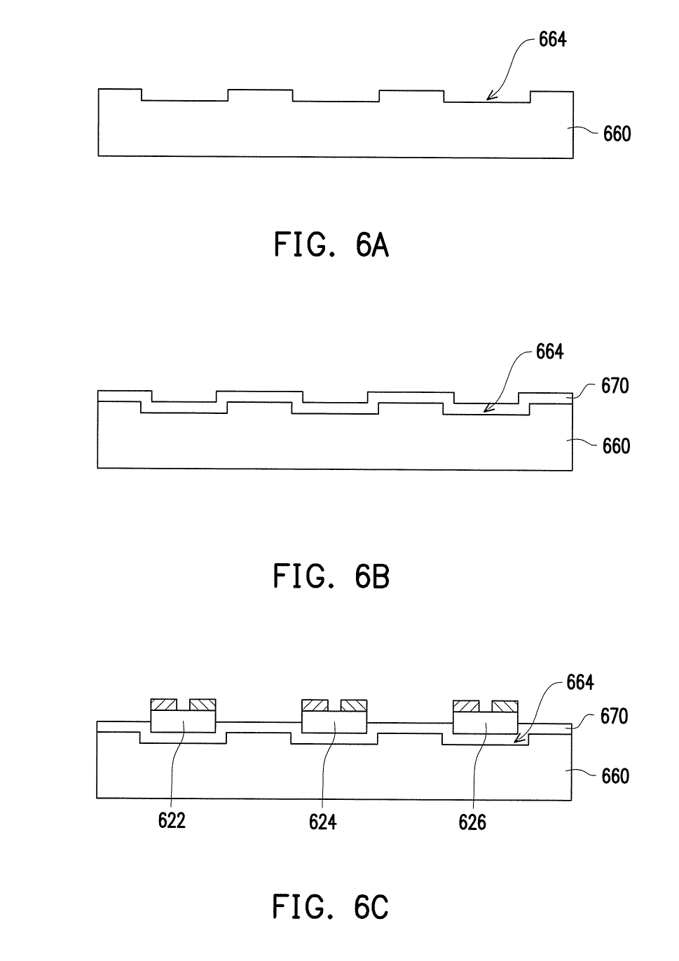

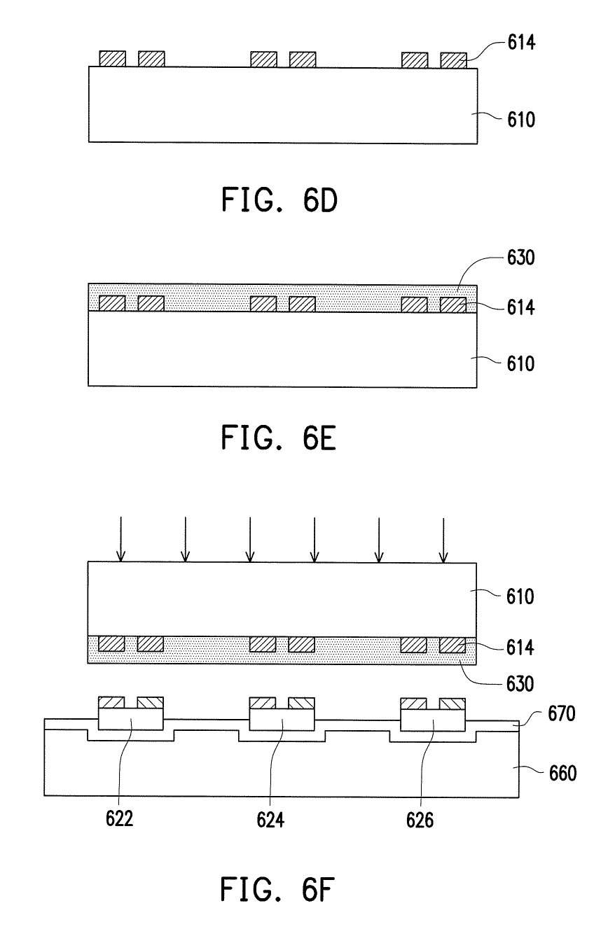

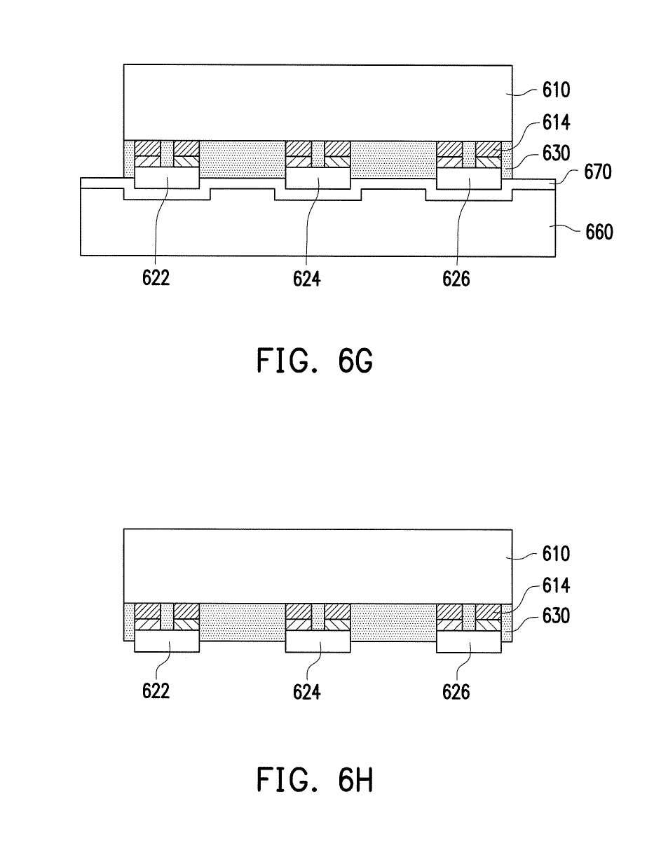

FIG. 6A through FIG. 6H illustrates a package process of a light emitting device according to an embodiment of the present disclosure. Firstly, as shown in FIG. 6A, a plurality of recesses 664 are formed on a surface 662 of a carrier 660. And then, a de-bonding layer 670 is Mimed over the entire surface 662 of the carrier 660. Next, as shown in FIG. 6C, light emitting devices 622, 624 and 626 (e.g. LEDs) capable of emitting lights in different colors are disposed in the recesses 664 and fixed on the carrier 660 through the de-bonding layer 670. The recesses 664 help to locating the light emitting devices 622, 624 and 626, and thus improve position precision in the following bonding process.

On the other hand, a carrier 610 having plural electrode contacts 614 as shown in FIG. 6D is provided. Herein, the carrier 610 may be a semiconductor substrate, a glass substrate, a circuit substrate or other applicable substrates, wherein the semiconductor substrate is, for example a drive IC, including electronic circuitry. Then, as shown in FIG. 6E, an anisotropic conductive layer 630 covering the electrode contacts 614 is formed on the carrier 610. The anisotropic conductive layer 630 may be the same as the anisotropic conductive layer 130 mentioned above, and the details are not repeated herein. Next, as shown in FIG. 6F, the carrier 610 with the electrode contacts 614 thereon is bonded to the carrier 660 through flip-chip bonding technique, such that the electrode contacts 614 are electrically connected to the corresponding light emitting devices 622, 624 and 626 through the anisotropic conductive layer 630, to form the structure as shown in FIG. 6G Then, as shown in FIG. 6H, the de-bonding layer 670 and the carrier 660 are removed to expose the light emitting devices 622, 624 and 626, to form the package structure 600.

As to the above, the package process of the present embodiment integrates light emitting devices 622, 624 and 626 capable of emitting lights in different colors on the carrier 610. The anisotropic conductive film 630 is taken as a bonding material, and thus no additional step for forming underfill is required. That is, a wafer level package can is accomplished, wherein all of the light emitting devices 622, 624 and 626 can be bonded to the carrier 610 through a single bonding step, and thus the process is simple, quick and suitable for mass production. Furthermore, the conventional solder paste for bonding process is not required, and thus use of material of lead and halogen in process can be prevented for environmental protection.

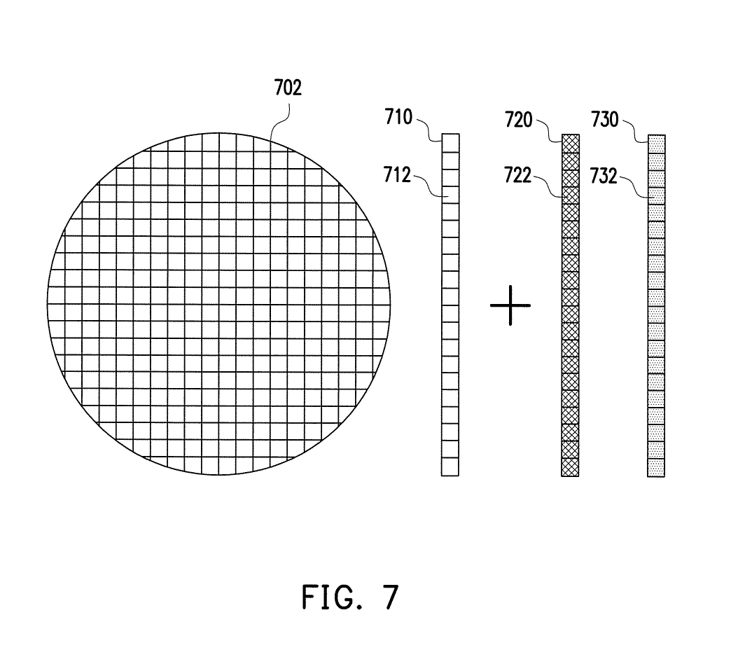

The aforementioned light emitting devices 622, 624 and 626 are, for example, LEDs formed on an epitaxial substrate. In practice, the light emitting devices 622, 624 and 626 may be LED chips formed by conducting a singulation step after a wafer-level process are completed. However, the disclosure is not limited thereto. For example, the light emitting devices 622, 624 and 626 of the package structure 600 may be arranged in an area array, to provide a full-color display. In order to accomplish simple and effective process, and take the consideration of position precision of bonding process, the wafer may be cut into strips of light emitting devices in the singulation step. Referring to FIG. 7, the first color light emitting strips 710, each comprising first color LEDs 712 connected with one another in series, may be formed by cutting the wafer 702. Similarly, the second color light emitting strip 720 and the third color light emitting strip 730 formed by cutting other wafers (not shown) may respectively comprise second color LEDs 722 connected with one another in series and third color LEDs 732 connected with one another in series. Referring to FIG. 6 and FIG. 7, the recesses 664 on the carrier 660 may be modified in to strip-shaped for accommodating the first color light emitting strip 710, the second color light emitting strip 720 and the third color light emitting strip 730, and steps of the package process mentioned in the previous embodiment can be conducted herein.

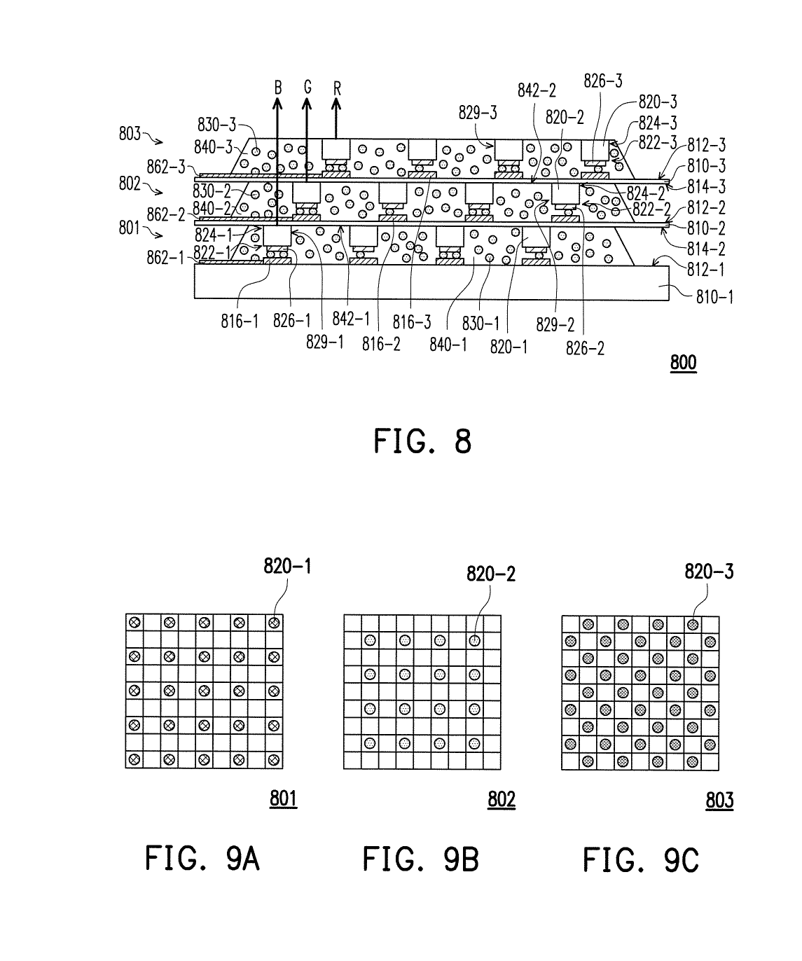

FIG. 8 illustrates a package structure 800 of a light emitting device capable of accomplishing full-color display according to an embodiment of the present disclosure. In the present embodiments, package units having light emitting device array are formed by flip-chip bonding technique, before laminating the package units together. For example, the package units having light emitting devices in different colors such as red, green and blue, are stacked with one another to form a full-color display. The package structure of the present embodiment provides simple and quick manufacturing process and is suitable for mass production. Furthermore, other embodiments modified from the present embodiment further provides solutions for optical issues such as light guiding or light mixing.

As shown in FIG. 8, the package structure 800 of the present embodiment includes a first package unit 801 and two second package units 802 and 803 stacked on the first package unit 801. The first package unit 801 includes a first carrier 810-1, plural first light emitting devices 820-1, plural first conductive devices 830-1 and a first encapsulant 840-1. The first carrier 810-1 has a first carrying surface 812-1 and a plurality of first electrode contacts 816-1 on the first carrying surface 812-1. Herein, the carrier 810-1 may be a semiconductor substrate, a glass substrate, a circuit substrate or other applicable substrates, wherein the semiconductor substrate is, for example a drive IC, including electronic circuitry. Furthermore, the first light emitting devices 820-1 are arranged in an array and disposed on the first carrying surface 812-1. With respect to the process, the first package unit 801 may be formed by the method mentioned in the previous embodiments. More specifically, the process as shown in FIG. 2A through FIG. 2D may be applied to bond the first light emitting devices 820-1 to the carrier 810-1 through an anisotropic conductive film and flip-chip bonding technique. And, a possible epitaxial substrate (not shown) may be removed after the bonding process, to form a surface for stacking the second package units 802 and 803.

After referring to the descriptions in the previous embodiments, a person having ordinary skill in the art should be able to realize and accomplish the process for manufacturing the first package unit 801, and thus the details are not repeated herein.

With respect to the structure, as shown in FIG. 8, the first light emitting devices 820-1 of the first package unit 801 may be first color LEDs fabricated on an epitaxial substrate, for example, the LEDs emitting blue lights B upward in FIG. 8. Each of the first light emitting devices 820-1 comprises a first top portion 822-1 facing the first carrier 810-1, a first bottom portion 824-1 opposite to the first top portion 822-1 and a first electrode 826-1 on the first top portion 822-1. The first conductive devices 830-1 respectively and electrically connect the first electrode 826-1 to the corresponding first electrode contact 816-1. The first encapsulant 840-1 is disposed on the first carrying surface 812-1 and at least covers the first electrode contacts 816-1, the first top portion 822-1 and the first electrode 826-1 of each of the first light emitting devices 820-1, and a side surface 829-1 of each of the first light emitting devices 820-1. In addition, a first surface 842-1 of the first encapsulant 840-1 is coplanar with the first bottom portion 824-1 of each of the first light emitting devices 820-1.

The first encapsulant 840-1 and the first conductive devices 830-1 may be respectively a first insulation body 840-1 and plural first conductive particles 830-1 in the first insulation body 840-1 of a first anisotropic conductive film. The insulation body 840-1 may be thermosetting polymer or thermoplastic polymer. Effect provided by taking the first anisotropic conductive layer as the bonding material can be referred to the descriptions of the previous embodiments, and the details are not repeated herein.

Similarly, the second package units 802 and 803 may be fabricated through the same process as the first package unit 801. Furthermore, since carriers of the second package units 802 and 803 stacked on the first package unit 801 may decrease intensity of light output of the package structure 800, the carriers of the second package units 802 and 803 may be thinned or made of transparent material.

As shown in FIG. 8, the second package unit 802 stacked on the first package unit 801 includes a second carrier 810-2, plural second light emitting devices 820-2, plural second conductive devices 830-2 and a second encapsulant 840-2. The second carrier 810-2 has a second carrying surface 812-2, a back surface 814-2 opposite to the second carrying surface 812-2, and plural second electrode contacts 816-2 on the second carrying surface 812-2. The back surface 814-2 of the second carrier 810-2 is bonded to the first surface 842-1 of the first encapsulant 840-1 and the first bottom portion 824-1 of each of the first light emitting devices 820-1. Furthermore, in order to increase the light output of the first package unit 801, the thickness of the second carrier 810-2 may be less than the thickness of the first carrier 810-1, or the second carrier 810-2 may be a transparent substrate. Conceivably, in other embodiments, the first carrier 810-1 may also be thinned to decrease the total thickness of the package structure 800.

In the present embodiment, the second light emitting devices 820-2 of the second package unit 802 may be second color LEDs fabricated on an epitaxial substrate, for example, the LEDs emitting green lights G upward in FIG. 8. The second light emitting devices 820-2 are arranged in an array and disposed on the second carrying surface 812-2. Each of the second light emitting devices 820-2 comprises a second top portion 822-2 facing the second carrier 810-2, a second bottom portion 824-2 opposite to the second top portion 822-2 and a third electrode 826-2 on the second top portion 822-2. The second conductive devices 830-2 respectively and electrically connect the third electrode 826-2 to the corresponding second electrode contact 816-2. The second encapsulant 840-2 is disposed on the second carrying surface 812-2 and at least covers the second electrode contacts 816-2, the second top portion 822-2 and the third electrode 826-2 of each of the second light emitting devices 820-2, and a side surface 829-2 of each of the second light emitting devices 820-2. In addition, a first surface 842-2 of the second encapsulant 840-2 is coplanar with the second bottom portion 824-2 of each of the second light emitting devices 820-2.

In the present embodiment, the second encapsulant 840-2 and the second conductive devices 830-2 may be respectively a second insulation body 840-2 and plural second conductive particles 830-2 in the second insulation body 840-2 of a second anisotropic conductive film. The second insulation body 840-2 may be thermosetting polymer or thermoplastic polymer. Effect provided by taking the second anisotropic conductive layer as the bonding material can be referred to the descriptions of the previous embodiments, and the details are not repeated herein.

Furthermore, the second package unit 803 stacked on the second package unit 802 includes a second carrier 810-3, plural second light emitting devices 820-3, plural second conductive devices 830-3 and a second encapsulant 840-3. The second carrier 810-3 has a second carrying surface 812-3, a back surface 814-3 opposite to the second carrying surface 812-3, and plural second electrode contacts 816-3 on the second carrying surface 812-3. The back surface 814-3 of the second carrier 810-3 is bonded to the first surface 842-2 of the second encapsulant 840-2 and the second bottom portion 824-2 of each of the second light emitting devices 820-2. Furthermore, in order to increase the light output of the first package unit 801 and the second package unit 802, the thickness of the second carrier 810-3 may be less than the thickness of the first carrier 810-1, or the second carrier 810-3 may be a transparent substrate. Conceivably, in other embodiments, the first carrier 810-1 may also be thinned to decrease the total thickness of the package structure 800.

In the present embodiment, the second light emitting devices 820-3 of the second package unit 803 may be third color LEDs fabricated on an epitaxial substrate, for example, the LEDs emitting red lights R upward in FIG. 8. The second light emitting devices 820-3 are arranged in an array and disposed on the second carrying surface 812-3. Each of the second light emitting devices 820-3 comprises a second top portion 822-3 facing the second carrier 810-3, a second bottom portion 824-3 opposite to the second top portion 822-3 and a third electrode 826-3 on the second top portion 822-3. The second conductive devices 830-3 respectively and electrically connect the third electrode 826-3 to the corresponding second electrode contact 816-3. The second encapsulant 840-3 is disposed on the second carrying surface 812-3 and at least covers the second electrode contacts 816-3, the second top portion 822-3 and the third electrode 826-3 of each of the second light emitting devices 820-3, and a side surface 829-3 of each of the second light emitting devices 820-3. In addition, a first surface 842-3 of the second encapsulant 840-3 is coplanar with the second bottom portion 824-3 of each of the second light emitting devices 820-3.

In the present embodiment, the second encapsulant 840-3 and the second conductive devices 830-3 may be respectively a second insulation body 840-3 and plural second conductive particles 830-3 in the second insulation body 840-3 of a second anisotropic conductive film. The second insulation body 840-3 may be thermosetting polymer or thermoplastic polymer. Effect provided by taking the second anisotropic conductive layer as the bonding material can be referred to the descriptions of the previous embodiments, and the details are not repeated herein.

Furthermore, as shown in FIG. 8, the first package unit 801 of the present embodiment may include a first circuit layer 862-1 disposed on the first carrying surface 812-1 of the first carrier 810-1, and the first encapsulant 840-1 exposes a periphery of the first carrier 810-1 and a portion of the first circuit layer 862-1. The first circuit layer 862-1 is electrically connected to the first electrode contacts 816-1, for transmitting electric signal between the outside and the first electrode contacts 816-1. The second package unit 802 may include a third circuit layer 862-2 disposed on the first carrying surface 812-2 of the second carrier 810-2, and the second encapsulant 840-2 exposes a periphery of the second carrier 810-2 and a portion of the third circuit layer 862-2. The third circuit layer 862-2 is electrically connected to the second electrode contacts 816-2, for transmitting electric signal between the outside and the second electrode contacts 816-2. In addition, the second package unit 803 may include a third circuit layer 862-3 disposed on the first carrying surface 812-3 of the second carrier 810-3, and the second encapsulant 840-3 exposes a periphery of the second carrier 810-3 and a portion of the third circuit layer 862-3. The third circuit layer 862-3 is electrically connected to the second electrode contacts 814-3, for transmitting electric signal between the outside and the second electrode contacts 816-3.

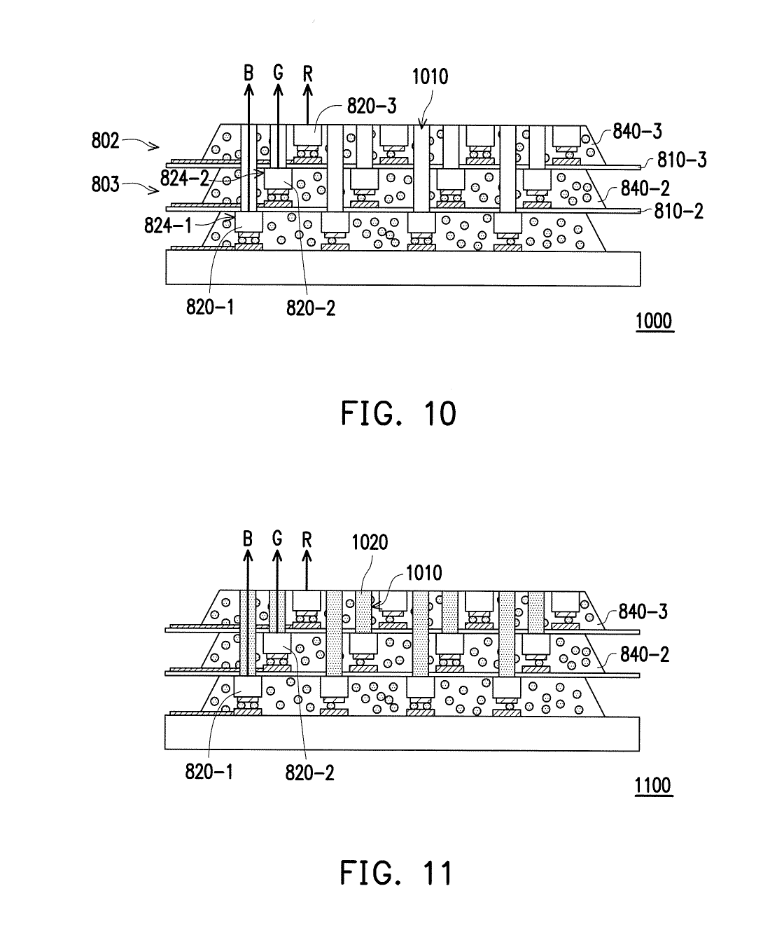

FIG. 9A through FIG. 9C respectively shows vertical projections of the first light emitting devices 820-1 of the first package unit 801, the second light emitting devices 820-2 of the second package unit 802 and the second light emitting devices 820-3 of the second package unit 803 on the first carrying surface 812-1 of the first carrier 810-1 (referring to FIG. 8). As shown in FIG. 9A through FIG. 9C, the vertical projections of the first light emitting devices 820-1 and the second light emitting devices 820-2 and 820-3 on the first carrying surface 812-1 (referring to FIG. 8) are not overlapped with one another and form an area array. Therefore, shading devices such as contacts or circuits in an upper layer are likely to block light emitted along an oblique direction from a lower light emitting device rather than light emitted along a vertical direction, and the problem of color interference is effectively eliminated.

FIG. 10 illustrates a package structure 1000 of a light emitting device according to an embodiment of the present disclosure. The package structure 1000 according to the present embodiment is partially similar to the package structure 800 according to the previous embodiment, except that the present embodiment further forms plural through holes 1010 serving as light guiding structures above the first light emitting devices 820-1 and the second light emitting devices 820-2 after the package process, to achieve high light extraction efficiency. To facilitate description, in the following embodiments of the disclosure, the same or similar devices are denoted by similar reference numerals as those in the previous embodiments. Some devices illustrated in the previous embodiments may be omitted, and descriptions of those omitted devices can be referred to the previous embodiments, and are not repeated herein.

More specifically, the through holes 1010 may be formed by removing the second package units 802 and/or the second package unit 803 over the first light emitting devices 820-1 and the second light emitting devices 820-2 through laser drilling, mechanical drilling or chemical etching, etc. An end of each of the through holes 1010 is connected to and exposes the first bottom portion 824-1 of the corresponding first light emitting device 820-1 or the second bottom portion 824-2 of the corresponding second light emitting device 820-2, such that the blue light B emitted from the first light emitting device 820-1 or the green light G emitted from the second light emitting device 820-2 can be transmitted to the outside through the through holes 1010.

In the present embodiment, selection of the material of the second encapsulants 840-2 and 840-3 and the second carriers 810-2 and 810-3 is much flexible, wherein transparent material or opaque material can be selected, because of forming the through holes 1010 in the second package units 802 and/or the second package unit 803.

FIG. 11 illustrates a package structure 1100 of a light emitting device according to an embodiment of the present disclosure. To facilitate description, in the following embodiments of the disclosure, the same or similar devices are denoted by similar reference numerals as those in the previous embodiments. Some devices illustrated in the previous embodiments may be omitted, and descriptions of those omitted devices can be referred to the previous embodiments, and are not repeated herein. The package structure 1100 according to the present embodiment is partially similar to the package structure 1000 according to the previous embodiment, except that the present embodiment further fills transparent material 1020 with high refractive index into the through holes 1010, so as to provide optical wave guiding effect for transmitting the blue lights B emitted from the first light emitting devices 820-1 and the green lights G emitted from the second light emitting devices 820-2 through total reflection between the transparent material 1020 and the second encapsulants 840-2 and 840-3. Herein, the refractive index of the transparent material 1020 is greater than the refractive index of the second encapsulants 840-2 and 840-3.

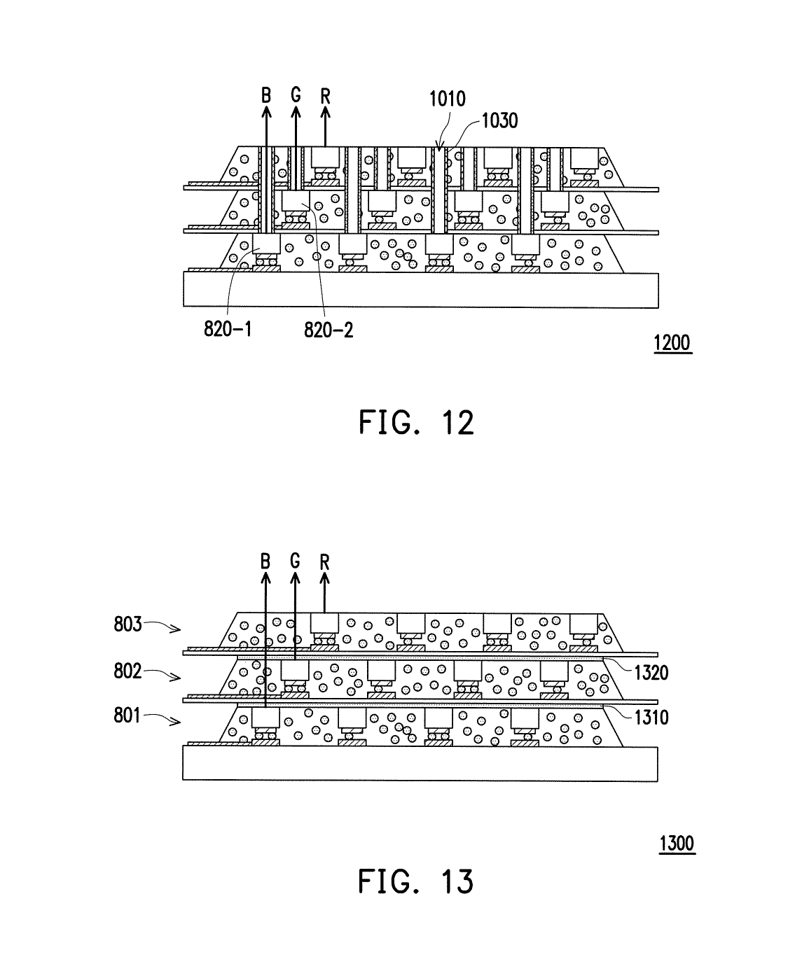

FIG. 12 illustrates a package structure 1200 of a light emitting device according to an embodiment of the present disclosure. To facilitate description, in the following embodiments of the disclosure, the same or similar devices are denoted by similar reference numerals as those in the previous embodiments. Some devices illustrated in the previous embodiments may be omitted, and descriptions of those omitted devices can be referred to the previous embodiments, and are not repeated herein. The package structure 1200 according to the present embodiment is partially similar to the package structure 1000 according to the previous embodiment, except that inner walls of the through holes 1010 of the present embodiment are covered by a reflection material 1030 such as metal, so as to reflect the blue lights B emitted from the first light emitting devices 820-1 and the green lights G emitted from the second light emitting devices 820-2 in the through holes 1010.

FIG. 13 illustrates a package structure 1300 of a light emitting device according to an embodiment of the present disclosure. To facilitate description, in the following embodiments of the disclosure, the same or similar devices are denoted by similar reference numerals as those in the previous embodiments. Some devices illustrated in the previous embodiments may be omitted, and descriptions of those omitted devices can be referred to the previous embodiments, and are not repeated herein. The package structure 1300 according to the present embodiment is partially similar to the package structure 800 according to the previous embodiment, except that the package structure 1300 of the present embodiment further includes an adhesive layer 1310 between the first package unit 801 and the second package unit 802, and an adhesive layer 1320 between the second package unit 802 and the second package unit 803. Herein, the adhesive layers 1310 and 1320 may be a non-conductive film or a UV adhesive. By using the adhesive layers 1310 and 1320 in the bonding process of the first package unit 801 and the second package units 802 and 803, selection of the material and modulation of the process parameters are much flexible.

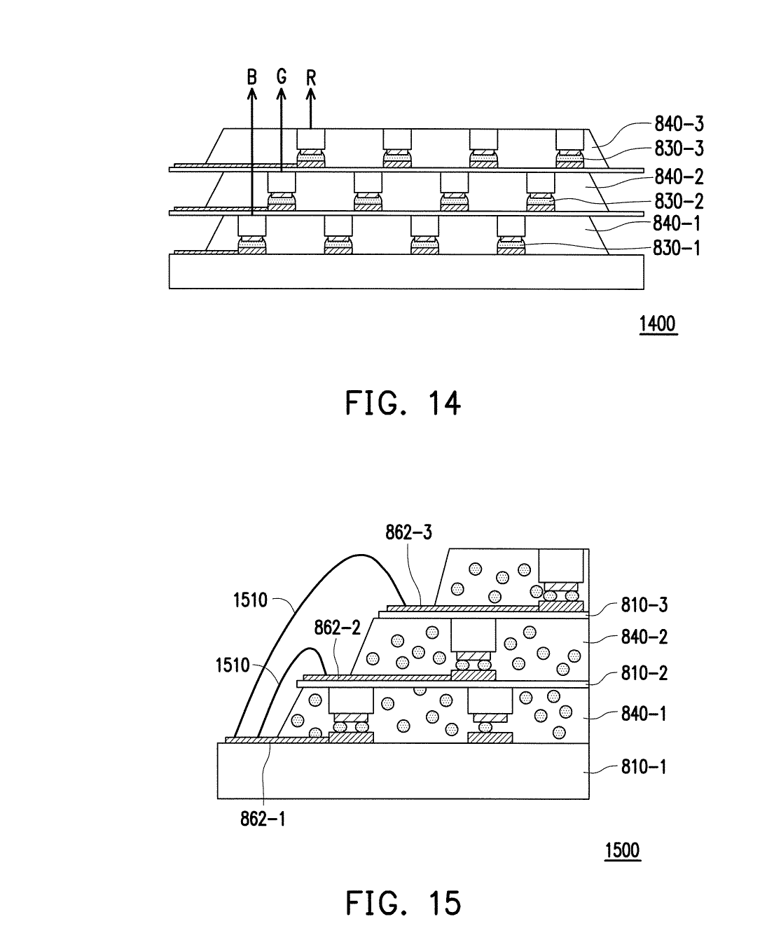

FIG. 14 illustrates a package structure 1400 of a light emitting device according to an embodiment of the present disclosure. To facilitate description, in the following embodiments of the disclosure, the same or similar devices are denoted by similar reference numerals as those in the previous embodiments. Some devices illustrated in the previous embodiments may be omitted, and descriptions of those omitted devices can be referred to the previous embodiments, and are not repeated herein. The package structure 1400 according to the present embodiment is partially similar to the package structure 1300 according to the previous embodiment, except that the present embodiment uses solder paste, instead of the anisotropic conductive film, for bonding the light emitting devices of the package to the electrode contacts.

More specifically, as shown in FIG. 14, the first conductive devices 830-1, the second conductive devices 830-2 and the second conductive devices 830-3 of the present embodiment are conductive bumps formed of solder paste. In addition, the first encapsulant 840-1, the second encapsulant 840-2 or the second encapsulant 840-3 may be a non-conductive film, underfill or a UV adhesive.

FIG. 15 is a partial view of a package structure 1500 of a light emitting device according to an embodiment of the present disclosure. To facilitate description, in the following embodiments of the disclosure, the same or similar devices are denoted by similar reference numerals as those in the previous embodiments. Some devices illustrated in the previous embodiments may be omitted, and descriptions of those omitted devices can be referred to the previous embodiments, and are not repeated herein. The package structure 1500 according to the present embodiment is partially similar to the package structure 800 according to the previous embodiment, except that the package structure 1500 of the present embodiment further includes plural conductive wires 1510, electrically connected between the first circuit layer 862-1 and the third circuit layer 862-2 or 862-3, or between two corresponding third circuit layers 862-2 and 862-3. In other words, the first encapsulant 840-1 and the second encapsulant 840-2 provide reliable support to sustain efficient structural strength for wire bonding process even if the second carriers 810-2 and 810-3 are thinned, such that the conductive wires 1510 can transmit the signals from different layer to the first carrier 810-1 for driving and control.

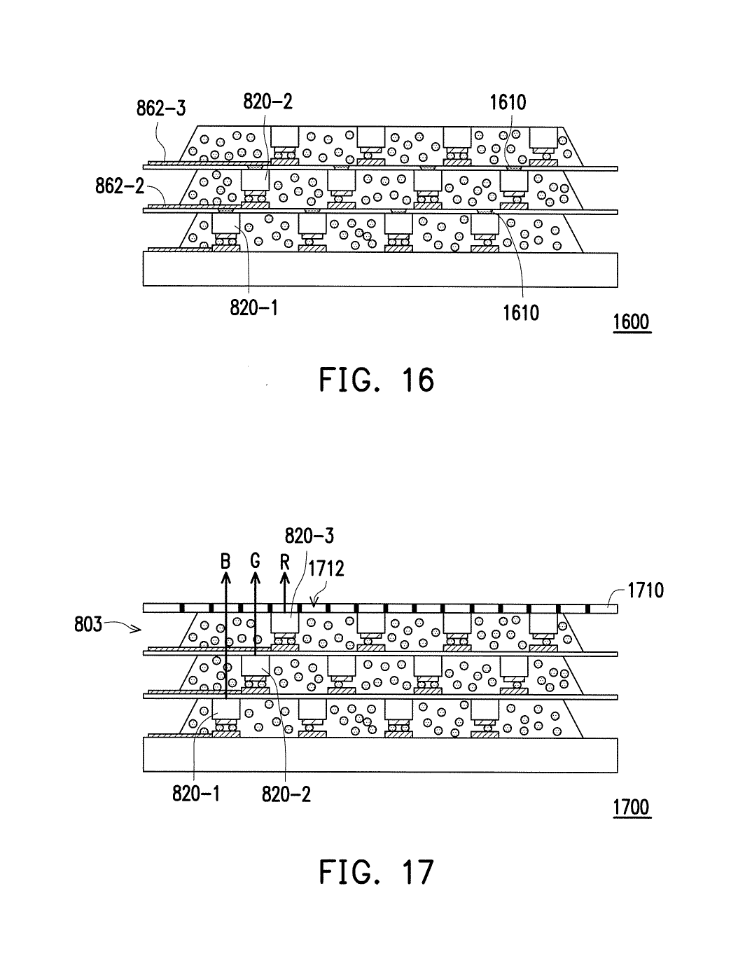

FIG. 16 illustrates a package structure 1600 of a light emitting device according to an embodiment of the present disclosure. To facilitate description, in the following embodiments of the disclosure, the same or similar devices are denoted by similar reference numerals as those in the previous embodiments. Some devices illustrated in the previous embodiments may be omitted, and descriptions of those omitted devices can be referred to the previous embodiments, and are not repeated herein. The package structure 1600 according to the present embodiment is partially similar to the package structure 1500 according to the previous embodiment, except that the present embodiment uses conductive vias 1610, instead of the conductive wires 1510 of the previous embodiment, to transmitting signals from different layers for integration and modulation. More specifically, the package structure 1600 comprises plural conductive vias 1610, each passing through the second carrier 810-2 or 810-3 and electrically connected between the corresponding third circuit layer 862-2 and the first light emitting device 820-1 there below, or electrically connected between the corresponding third circuit layer 862-3 and the second light emitting device 820-2 there below.

FIG. 17 illustrates a package structure 1700 of a light emitting device according to an embodiment of the present disclosure. To facilitate description, in the following embodiments of the disclosure, the same or similar devices are denoted by similar reference numerals as those in the previous embodiments. Some devices illustrated in the previous embodiments may be omitted, and descriptions of those omitted devices can be referred to the previous embodiments, and are not repeated herein. The package structure 1700 according to the present embodiment is partially similar to the package structure 800 according to the previous embodiment, except that the package structure 1700 of the present embodiment further includes a black matrix layer 1710 disposed over the second package unit 803. The black matrix layer 1710 has plural transparent regions 1712 respectively corresponding to the first light emitting devices 820-1 and the second light emitting devices 820-2 and 820-3, so as to define plural pixel regions of full color display. Herein, the black matrix layer 1710 is for example a transparent cover formed with black oblique regions thereon.

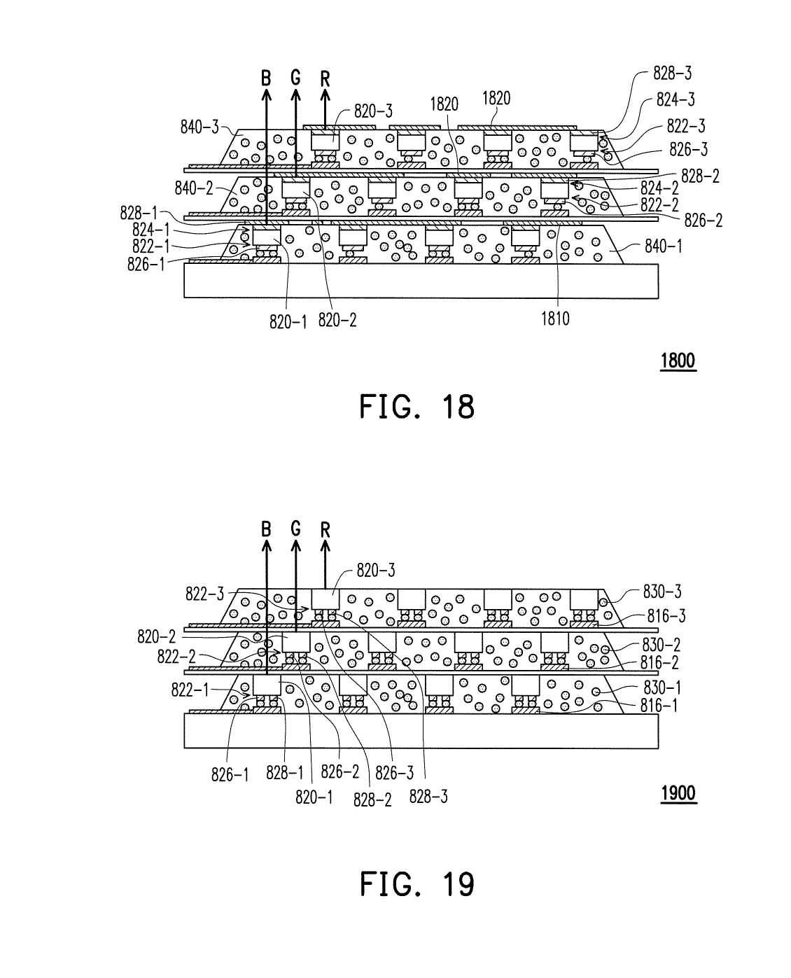

FIG. 18 illustrates a package structure 1800 of a light emitting device according to an embodiment of the present disclosure. In the present embodiment, the same or similar devices are denoted by similar reference numerals as those in the previous embodiments. Some devices illustrated in the previous embodiments may be omitted, and descriptions of those omitted devices can be referred to the previous embodiments. Main difference between the present embodiment and the previous embodiment is illustrated below.

In the present embodiment, the light emitting devices 820-1 and the second light emitting devices 820-2 and 820-3 are for example vertical-type LEDs. More specifically, each of the first light emitting device 820-1 includes a second electrode 828-1 on the first bottom portion 824-1 besides the first electrode 826-1 on the first top portion 822-1, wherein the first electrode 826-1 may be a P-type electrode of LED, and the second electrode 828-1 may be an N-type electrode of LED. Each of the second light emitting device 820-2 includes a fourth electrode 828-2 on the second bottom portion 824-2 besides the third electrode 826-2 on the second top portion 822-2, wherein the third electrode 826-2 may be a P-type electrode of LED, and the fourth electrode 828-2 may be an N-type electrode of LED. In addition, each of the second light emitting device 820-3 includes a fourth electrode 828-3 on the second bottom portion 824-3 besides the third electrode 826-3 on the second top portion 822-3, wherein the third electrode 826-3 may be a P-type electrode of LED, and the fourth electrode 828-3 may be an N-type electrode of LED.

Optionally, after an epitaxial substrate (not shown) of the first package unit 801 is removed, a second circuit layer 1810 connecting the second electrodes 128 can be formed on the first encapsulant 840-1 to form a common N-type electrode. In addition, after an epitaxial substrate (not shown) of the second package unit 802 or 803 is removed, a fourth circuit layer 1820 connecting the second electrodes 828-2 or 828-3 can be formed on the second encapsulant 840-2 or 840-3 to form a common N-type electrode. Herein, the second circuit layer 1810 or the fourth circuit layer 1820 may be formed of metal such as gold, copper, aluminum, chromium, titanium, etc., or may be a transparent conductive layer formed of oxide of metals such as indium tin oxide (ITO) or indium zinc oxide (IZO).

FIG. 19 illustrates a package structure 1900 of a light emitting device according to an embodiment of the present disclosure. The package structure 1900 according to the present embodiment is partially similar to the package structure 1800 according to the previous embodiment, except that the first light emitting devices 820-1 and the second light emitting devices 820-2 and 820-3 of the package structure 1900 are horizontal-type LEDs. To facilitate description, in the following embodiments of the disclosure, the same or similar devices are denoted by similar reference numerals as those in the previous embodiments. Some devices illustrated in the previous embodiments may be omitted, and descriptions of those omitted devices can be referred to the previous embodiments, and are not repeated herein.

As shown in FIG. 19, each of the first light emitting devices 820-1 of the present embodiment has a first electrode 826-1 and a second electrode 828-1 on the first top portion 822-1, and the first electrode 826-1 and the second electrode 828-1 are respectively and electrically connected to their corresponding first electrode contacts 816-1 through the first conductive devices 830-1. Each of the second light emitting devices 820-2 of the present embodiment has a third electrode 826-2 and a fourth electrode 828-2 on the second top portion 822-2, and the third electrode 826-2 and the fourth electrode 828-2 are respectively and electrically connected to their corresponding second electrode contacts 816-2 through the second conductive devices 830-2. In addition, each of the second light emitting devices 820-3 of the present embodiment has a third electrode 826-3 and a fourth electrode 828-3 on the second top portion 822-3, and the third electrode 826-3 and the fourth electrode 828-3 are respectively and electrically connected to their corresponding second electrode contacts 816-3 through the second conductive devices 830-3.

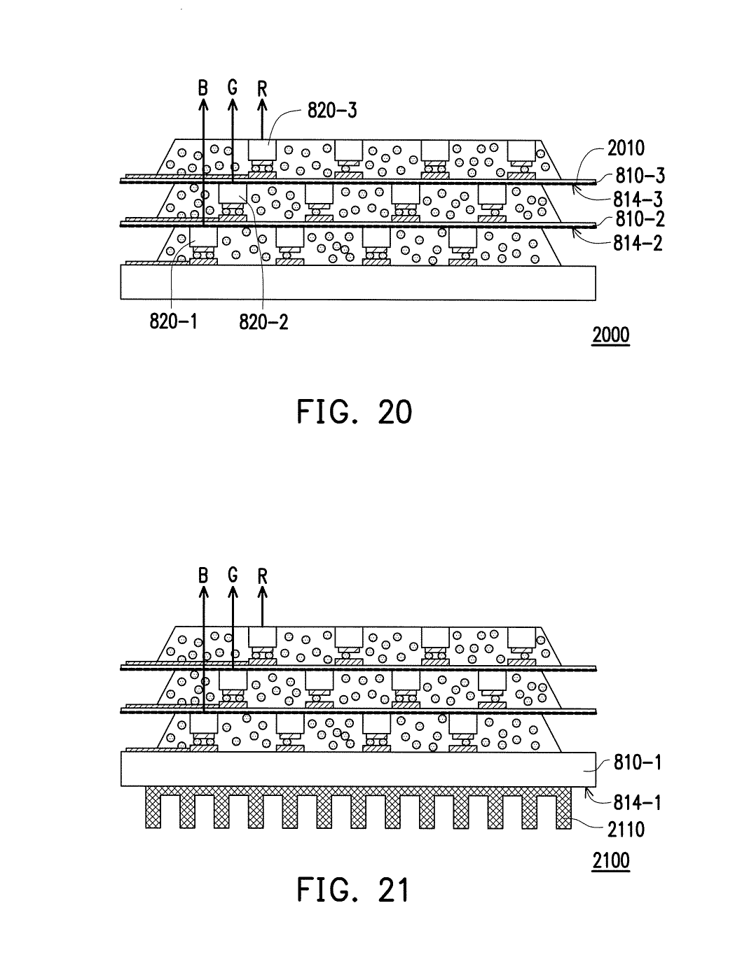

FIG. 20 illustrates a package structure 2000 of a light emitting device according to an embodiment of the present disclosure. The package structure 2000 according to the present embodiment is partially similar to the package structure 800 according to the previous embodiment, except that the second carriers 810-2 and 810-3 of the package structure 2000 are provided with plural optical micro structures 2010 on their back surfaces 814-2 and 814-3. To facilitate description, in the following embodiments of the disclosure, the same or similar devices are denoted by similar reference numerals as those in the previous embodiments. Some devices illustrated in the previous embodiments may be omitted, and descriptions of those omitted devices can be referred to the previous embodiments, and are not repeated herein.

More specifically, as shown in FIG. 20, the optical micro structures 2010 of the present embodiment may be micro lenses or optical modulation patterns formed on the back surfaces 814-2 and 814-3 of the second carriers 810-2 and 810-3. In other words, the micro lenses or the optical modulation patterns are capable of achieving light convergence or other specific optical effects in the package structure 2000, such that lights emitted from the first light emitting devices 820-1 and the second light emitting devices 820-2 and 820-3 can be converged.

FIG. 21 illustrates a package structure 2100 of a light emitting device according to an embodiment of the present disclosure. The package structure 2100 according to the present embodiment is partially similar to the package structure 800 according to the previous embodiment, except that the package structure 2100 further includes a heat sink 2110 disposed on the back surface 814-1 of the first carrier 810-1 to provide the package structure 2100 superior heat dissipation effect. To facilitate description, in the following embodiments of the disclosure, the same or similar devices are denoted by similar reference numerals as those in the previous embodiments. Some devices illustrated in the previous embodiments may be omitted, and descriptions of those omitted devices can be referred to the previous embodiments, and are not repeated herein.

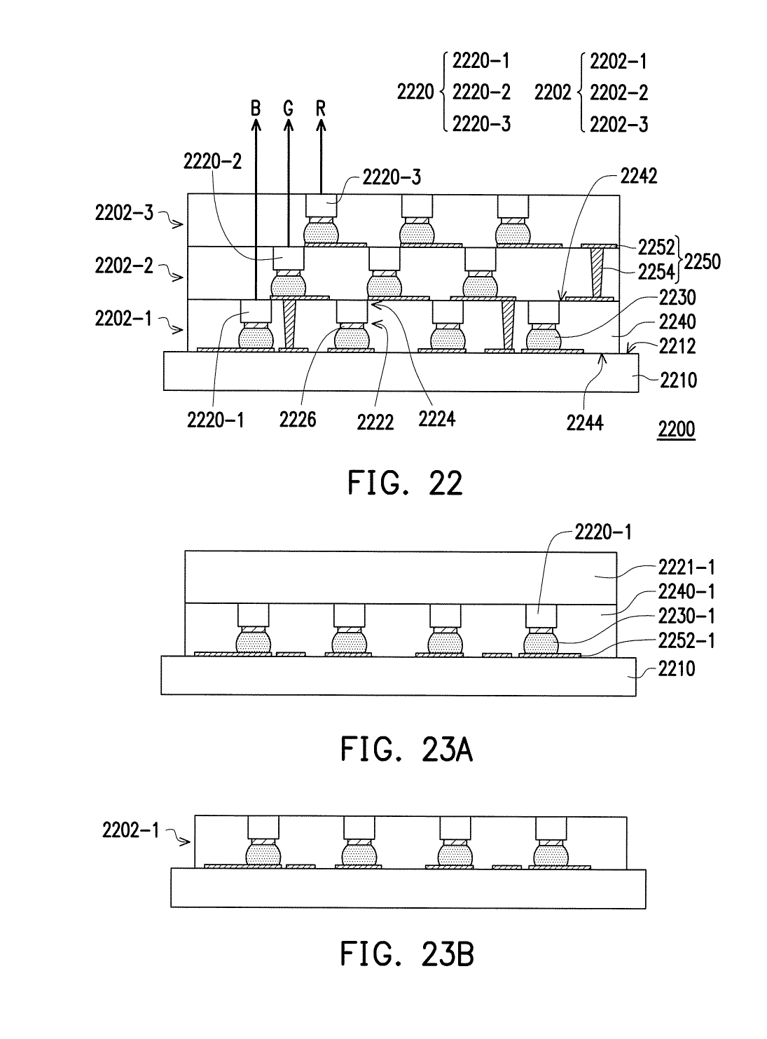

FIG. 22 illustrates a package structure 2200 of a light emitting device capable of accomplishing full-color display according to an embodiment of the present disclosure. In the present embodiment, stacked package units having light emitting device arrays are formed by flip-chip bonding technique and build-up process. For example, the package units having light emitting devices in different colors such as red, green and blue, are stacked with one another to form a full-color display. The package structure of the disclosure provides simple and quick manufacturing process and is suitable for mass production. Furthermore, solutions for optical issues such as light guiding or light mixing are also provided.

As shown in FIG. 22, the package structure 2200 includes a carrier 2210, plural package units 2202 and an interconnection structure 2250. The carrier 2210 has a carrying surface 2212. Herein, the carrier 2210 may be a semiconductor substrate, a glass substrate, a circuit substrate or other applicable substrates, wherein the semiconductor substrate is, for example a drive IC, including electronic circuitry.

The package units 2202 are sequentially stacked on the carrying surface 2212, and each of the package units 2202 includes an encapsulant 2240, plural light emitting devices 2220 and plural conductive bumps 2230. Each encapsulant 2240 has a first surface 2242 and a second surface 2244 opposite to the first surface 2242, wherein the second surface 2244 of an upper encapsulant 2240 is bonded to the first surface 2242 of a lower encapsulant 2240 of another package unit 2202. The light emitting devices 2220 are arranged in an array and embedded in the first surfaces 2242 of the encapsulants 2240.

Each of the light emitting devices 2220 comprises a top portion 2222 facing the carrier 2210, a bottom portion 2224 opposite to the top portion 2222 and a first electrode 2226 on the top portion 2222. The first surface 2242 of the encapsulant 2240 is coplanar with the bottom portion 2224 of each of the light emitting devices 2220. The conductive bumps 2230 are embedded in the second surfaces 2244 of the encapsulants 2240. The interconnection structure 2250 is located in the encapsulants 2240 of the package units 2202, and the interconnection structure 2250 comprises plural first circuit layers 2252 and plural conductive vias 2254. The first circuit layers 2252 are disposed between two adjacent encapsulants 2240 or between the carrier 2210 and the encapsulant 2240 adjacent to the carrier 2210, and electrically connected to the corresponding light emitting devices 2220 through the conductive bumps 2230. The conductive vias 2254 pass through the corresponding encapsulants 2240 and electrically connected between the corresponding first circuit layers 2252.

In the present embodiment, the light emitting devices 2220 of each of the package units 2202 may be LEDs fabricated on an epitaxial substrate, and the light emitting devices 2220 of different package units 2202 emit lights in different colors.

More specifically, as shown in FIG. 22, the package structure 2200 of the present embodiment includes a first package unit 2202-1, a second package unit 2202-2 and a second package unit 2202-3 stacked with one another. The light emitting devices 2220-1 of the first package unit 2202-1 may be first color LEDs fabricated on an epitaxial substrate, for example, the LEDs emitting blue lights B upward in FIG. 22. The light emitting devices 2220-2 of the second package unit 2202-2 may be second color LEDs fabricated on an epitaxial substrate, for example, the LEDs emitting green lights G upward in FIG. 22. The light emitting devices 2220-3 of the third package unit 2202-3 may be third color LEDs fabricated on an epitaxial substrate, for example, the LEDs emitting red lights R upward in FIG. 22.

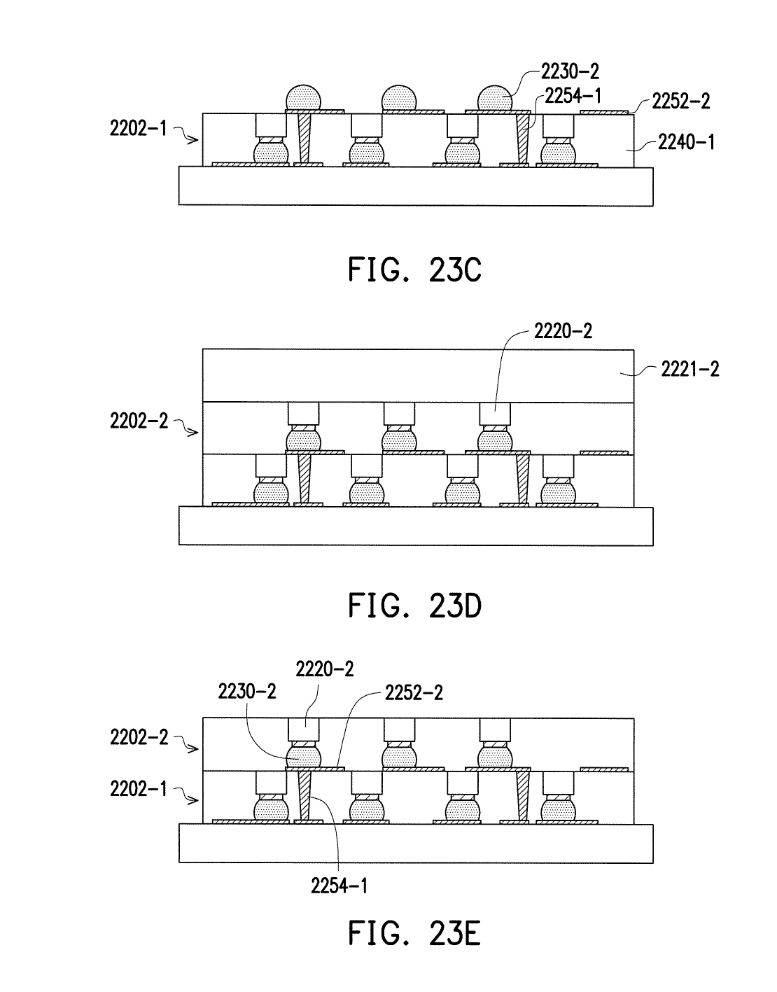

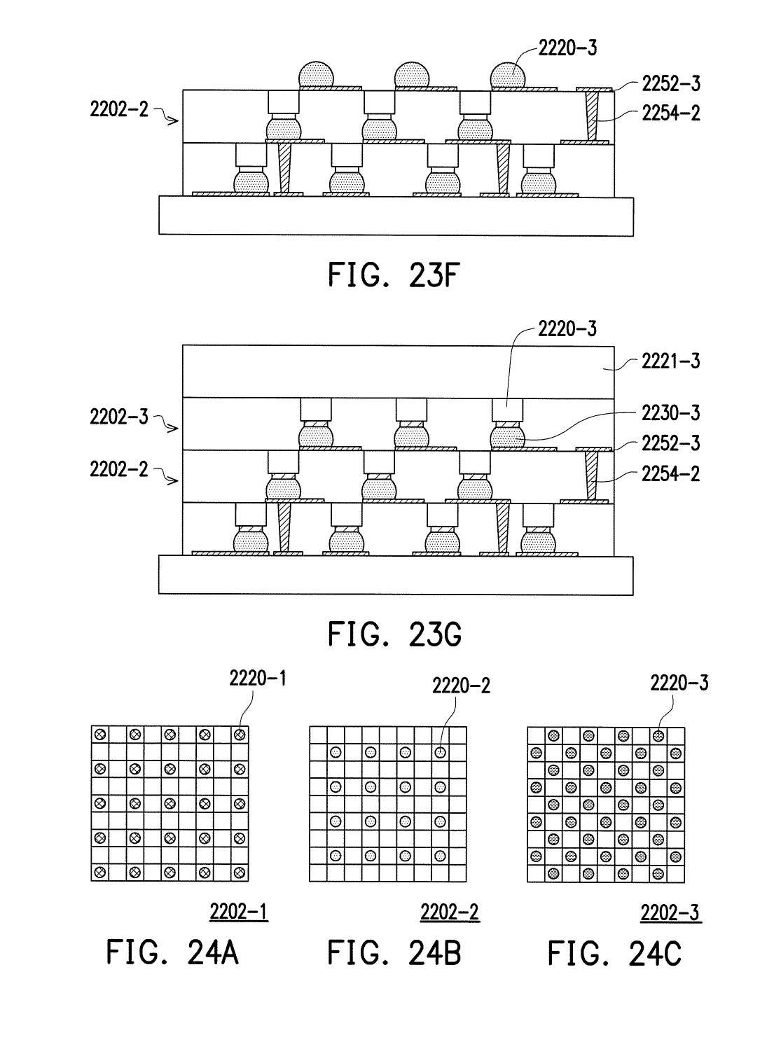

FIG. 23A through FIG. 23G illustrate a package process of the package structure 2200 of FIG. 22. Firstly, as shown in FIG. 23A, the light emitting devices 2220-1 of a first layer accompanying with the epitaxial substrate 2221-1 are bonded to the carrier 2210 through flip-chip bonding technique, wherein the light emitting devices 2220-1 are electrically connected to the first circuit layer 2252-1 on the carrier 2210 through the conductive bumps 2230-1. In this step, the conductive bumps 2230-1 may be formed of conventional solder paste. In addition, a non-conductive film, an underfill or a UV adhesive can be filled into the space between the epitaxial substrate 2221-1 and the carrier 2210, to form the encapsulant 2240-1.

Then, as shown in FIG. 23B, the epitaxial substrate 2221-1 is removed by lift-off technique. Here, the first package unit 2202-1 in the lower layer is formed. Next, as shown in FIG. 23C, another first circuit layer 2252-2, plural conductive vias 2254-1 passing through the encapsulant 2240-1 and plural conductive bumps 2230-2 are formed by performing etching, deposition, electroplating, or any possible process on the first package unit 2202-1.

Then, as shown in FIG. 23D and FIG. 23E, the aforementioned process are repeated to bond the light emitting devices 2220-2 of a second layer accompanying with the epitaxial substrate 2221-2 to the first package unit 2202-1 through flip-chip bonding technique, and the epitaxial substrate 2221-2 is then removed to form the second package unit 2202-2 on the first package unit 2202-1. The light emitting devices 2220-2 are electrically connected to the first circuit layer 2252-2 on the first package unit 2202-1 through the conductive bumps 2230-2, and the first circuit layer 2252-2 is electrically connected to circuits of lower layers through the conductive vias 2254-1.

Next, as shown in FIG. 23F, another first circuit layer 2252-3, plural conductive vias 2254-2 passing through the encapsulant 2240-2 and plural conductive bumps 2230-3 are formed by performing etching, deposition, electroplating, or any possible process on the second package unit 2202-2.

Then, as shown in FIG. 23G, the light emitting devices 2220-3 of a third layer accompanying with the epitaxial substrate 2221-3 are bonded to the second package unit 2202-2 through flip-chip bonding technique, to form the third package unit 2202-3 on the second package unit 2202-2. Herein, the epitaxial substrate 2221-3 may be selectively removed or may be remained to protect the third package unit 2202-3 in the uppermost layer, and enhance structural strength of the package structure 2220. The light emitting devices 2220-3 are electrically connected to the first circuit layer 2252-3 on the first package unit 2202-2 through the conductive bumps 2230-3, and the first circuit layer 2252-3 is electrically connected to circuits of lower layers through the conductive vias 2254-2.

FIG. 24A through FIG. 24C respectively shows vertical projections of the light emitting devices 2220-1 of the first package unit 2202-1, the light emitting devices 2220-2 of the second package unit 2202-2 and the light emitting devices 2220-3 of the third package unit 2202-3 on the carrying surface 2212 of the carrier 2210 (referring to FIG. 22). As shown in FIG. 24A through FIG. 24C, the vertical projections of the light emitting devices 2220-1, 2220-2 and 2220-3 on the carrying surface 2212-1 (referring to FIG. 22) are not overlapped with one another and form an area array. Therefore, shading devices such as contacts or circuits in an upper layer are likely to block light emitted along an oblique direction from a lower light emitting device rather than light emitted along a vertical direction, and the problem of color interference is effectively eliminated.

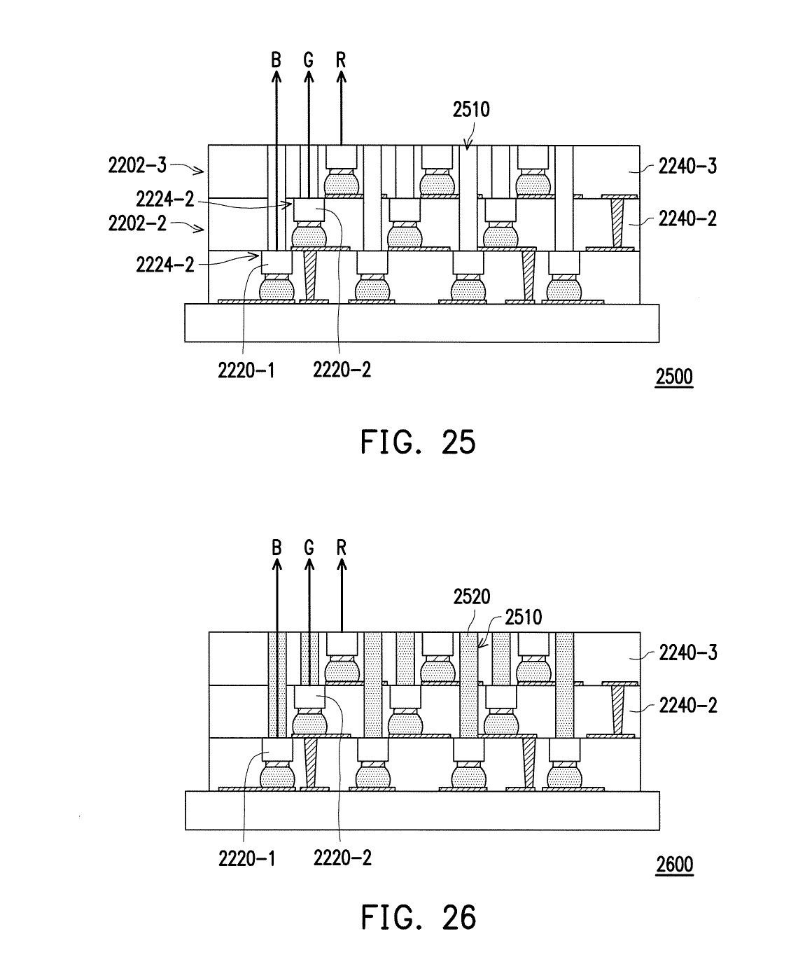

FIG. 25 illustrates a package structure 2500 of a light emitting device according to an embodiment of the present disclosure. The package structure 2500 according to the present embodiment is partially similar to the package structure 2200 according to the previous embodiment, except that the present embodiment further forms plural through holes 2510 serving as light guiding structures above the light emitting devices 2220-1 and 2220-2 after the package process, to achieve high light extraction efficiency. To facilitate description, in the following embodiments of the disclosure, the same or similar devices are denoted by similar reference numerals as those in the previous embodiments. Some devices illustrated in the previous embodiments may be omitted, and descriptions of those omitted devices can be referred to the previous embodiments, and are not repeated herein.

More specifically, the through holes 2510 may be formed by removing the package units 2202-2 and/or the package unit 2202-3 above the light emitting devices 2220-1 and 2220-2 through laser drilling, mechanical drilling or chemical etching, etc. An end of each of the through holes 2510 is connected to and exposes the first bottom portion 2224-1 of the corresponding light emitting device 2220-1 or the bottom portion 2224-2 of the corresponding light emitting device 2220-2, such that the blue light B emitted from the light emitting device 2220-1 or the green light G emitted from the light emitting device 2220-2 can be transmitted to the outside through the through holes 2510.

In the present embodiment, selection of the material of the encapsulants 2240-2 and 2240-3 is much flexible, wherein transparent material or opaque material can be selected, because of forming the through holes 2510 in the package units 2202-2 and/or the package unit 2202-3.

FIG. 26 illustrates a package structure 2600 of a light emitting device according to an embodiment of the present disclosure. The package structure 2600 according to the present embodiment is partially similar to the package structure 2500 according to the previous embodiment, except that the present embodiment further fills transparent material 2520 with high refractive index into the through holes 2510, so as to provide optical wave guiding effect for transmitting the blue lights B emitted from the light emitting devices 2220-1 and the green lights G emitted from the light emitting devices 2220-2 through total reflection between the transparent material 2520 and the encapsulants 2240-2 and 2240-3. Herein, the refractive index of the transparent material 2520 is greater than the refractive index of the encapsulants 2240-2 and 2240-3. To facilitate description, in the following embodiments of the disclosure, the same or similar devices are denoted by similar reference numerals as those in the previous embodiments. Some devices illustrated in the previous embodiments may be omitted, and descriptions of those omitted devices can be referred to the previous embodiments, and are not repeated herein.

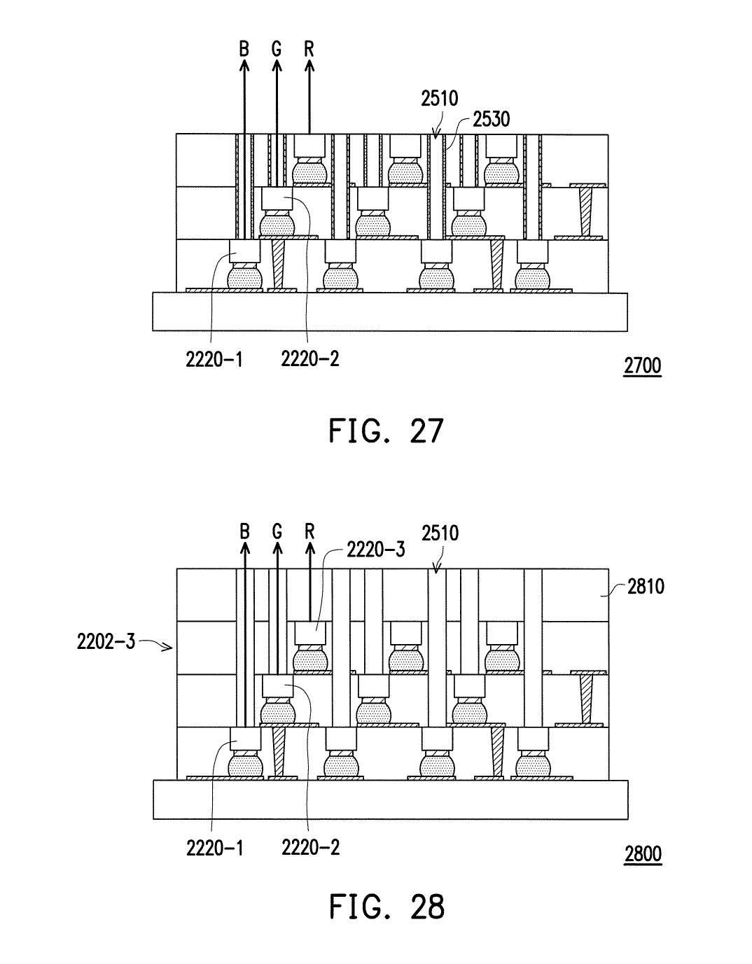

FIG. 27 illustrates a package structure 2700 of a light emitting device according to an embodiment of the present disclosure. The package structure 2700 according to the present embodiment is partially similar to the package structure 2500 according to the previous embodiment, except that inner walls of the through holes 2510 of the present embodiment are covered by a reflection material 2530 such as metal, so as to reflect the blue lights B emitted from the light emitting devices 2220-1 and the green lights G emitted from the light emitting devices 2220-2 in the through holes 2510. To facilitate description, in the following embodiments of the disclosure, the same or similar devices are denoted by similar reference numerals as those in the previous embodiments. Some devices illustrated in the previous embodiments may be omitted, and descriptions of those omitted devices can be referred to the previous embodiments, and are not repeated herein.

FIG. 28 illustrates a package structure 2800 of a light emitting device according to an embodiment of the present disclosure. The package structure 2800 according to the present embodiment is partially similar to the package structure 2500, 2600 or 2700 according to the previous embodiments, except that a cover layer 2810 is formed over the third package unit 2202-3 in the present embodiment, and is penetrated by the light guiding structures such as through holes 2510, the transparent material 2520 (as shown in FIG. 26), the reflective material (as shown in FIG. 27). Likely, similar light guiding structures can also be formed over the light emitting devices 2220-3. By which, lights emitted from the light emitting devices 2220-1, 2220-2 and 2220-3 converge to improve quality of light output. To facilitate description, in the following embodiments of the disclosure, the same or similar devices are denoted by similar reference numerals as those in the previous embodiments. Some devices illustrated in the previous embodiments may be omitted, and descriptions of those omitted devices can be referred to the previous embodiments, and are not repeated herein.

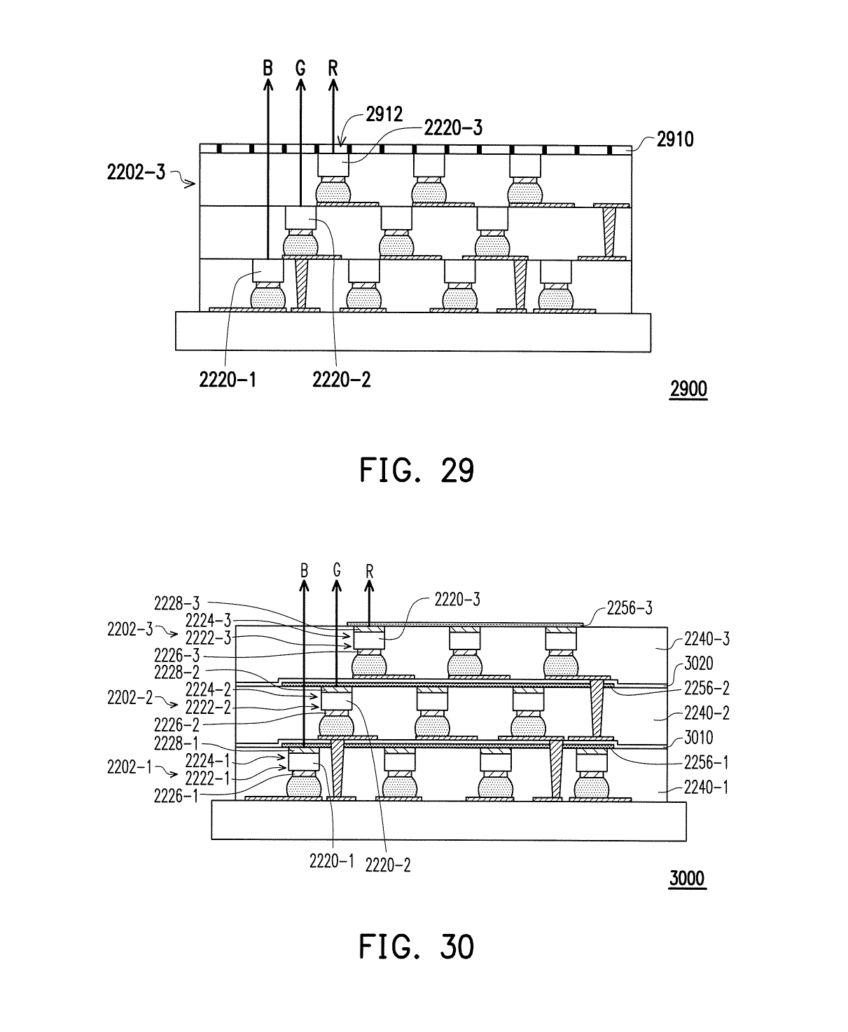

FIG. 29 illustrates a package structure 2900 of a light emitting device according to an embodiment of the present disclosure. The package structure 2900 according to the present embodiment is partially similar to the package structure 2200 according to the previous embodiment, except that the package structure 2900 of the present embodiment further includes a black matrix layer 2910 disposed over the third package unit 2202-3. The black matrix layer 2910 has plural transparent regions 2912 respectively corresponding to the light emitting devices 2220-1, 2220-2 and 2220-3, so as to define plural pixel regions of full color display. Herein, the black matrix layer 2910 is for example a transparent cover formed with black oblique regions thereon. To facilitate description, in the following embodiments of the disclosure, the same or similar devices are denoted by similar reference numerals as those in the previous embodiments. Some devices illustrated in the previous embodiments may be omitted, and descriptions of those omitted devices can be referred to the previous embodiments, and are not repeated herein.

FIG. 30 illustrates a package structure 3000 of a light emitting device according to an embodiment of the present disclosure. In the present embodiment, the same or similar devices are denoted by similar reference numerals as those in the previous embodiments. Some devices illustrated in the previous embodiments may be omitted, and descriptions of those omitted devices can be referred to the previous embodiments. Main difference between the present embodiment and the previous embodiment is illustrated below.

In the present embodiment, the light emitting devices 2220-1, 2220-2 and 2220-3 are vertical-type LEDs, for example. More specifically, each of the light emitting device 2220-1 includes a second electrode 2228-1 on the bottom portion 2224-1 besides the first electrode 2226-1 on the top portion 2222-1, wherein the first electrode 2226-1 may be a P-type electrode of LED, and the second electrode 2228-1 may be an N-type electrode of LED. Each of the light emitting device 2220-2 includes a second electrode 2228-2 on the bottom portion 2224-2 besides the first electrode 2226-2 on the top portion 2222-2, wherein the first electrode 2226-2 may be a P-type electrode of LED, and the second electrode 2228-2 may be an N-type electrode of LED. In addition, each of the light emitting device 2220-3 includes a second electrode 2228-3 on the bottom portion 2224-3 besides the first electrode 2226-3 on the top portion 2222-3, wherein the first electrode 2226-3 may be a P-type electrode of LED, and the second electrode 2228-3 may be an N-type electrode of LED.

Optionally, after an epitaxial substrate 2221-1 (as shown in FIG. 23A) of the first package unit 2202-1 is removed, a second circuit layer 2256-1 connecting the second electrodes 2228-1 can be formed on the encapsulant 2240-1 to form a common N-type electrode. Or, after an epitaxial substrate 2221-2 (not shown) of the second package unit 2202-2 is removed, a second circuit layer 2256-2 connecting the second electrodes 2228-2 may be formed on the encapsulant 2240-2 to form a common N-type electrode. Furthermore, after an epitaxial substrate 2221-3 (not shown) of the third package unit 2202-3 is removed, a second circuit layer 2256-3 connecting the second electrodes 2228-3 may be formed on the encapsulant 2240-3 to form a common N-type electrode. Herein, the second circuit layer 2256-1, 2256-2 or 2256-3 may be formed of metal such as gold, copper, aluminum, chromium, titanium, etc., or may be a transparent conductive layer formed of oxide of metals such as indium tin oxide (ITO) or indium zinc oxide (IZO).

In addition, the package structure 3000 further includes insulation layers 3010 and 3020 respectively disposed between the encapsulants 2240-1 and 2240-2 and between the encapsulants 2240-2 and 2240-3, to insulate the corresponding second circuit layers 2256-1 and 2256-2 from other interconnection structures.

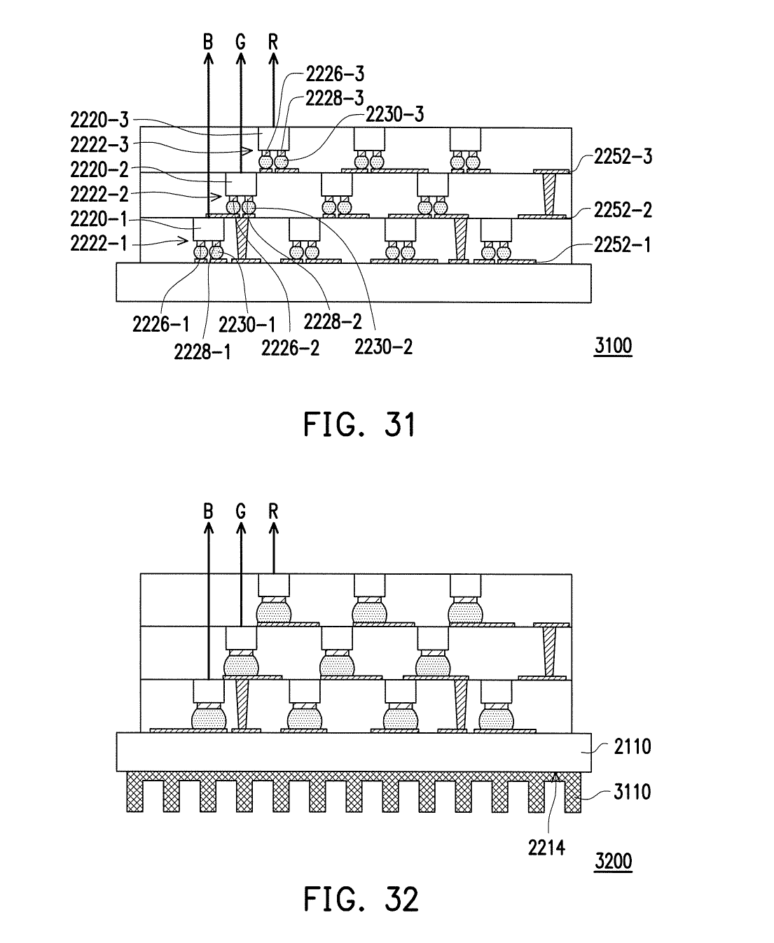

FIG. 31 illustrates a package structure 3100 of a light emitting device according to an embodiment of the present disclosure. To facilitate description, in the following embodiments of the disclosure, the same or similar devices are denoted by similar reference numerals as those in the previous embodiments. Some devices illustrated in the previous embodiments may be omitted, and descriptions of those omitted devices can be referred to the previous embodiments, and are not repeated herein. The package structure 3100 according to the present embodiment is partially similar to the package structure 3000 according to the previous embodiment, except that the light emitting devices 2220-1, 2220-2 and 2220-3 of the package structure 3100 are horizontal-type LEDs.

As shown in FIG. 31, each of the light emitting devices 2220-1 of the present embodiment has a first electrode 2226-1 and a second electrode 2228-1 on the top portion 2222-1, and the first electrode 2226-1 and the second electrode 2228-1 are respectively and electrically connected to the corresponding first circuit layer 2252-1 through the conductive bumps 2230-1. Each of the light emitting devices 2220-2 of the present embodiment has a first electrode 2226-2 and a second electrode 2228-2 on the top portion 2222-2, and the first electrode 2226-2 and the second electrode 2228-2 are respectively and electrically connected to the corresponding first circuit layer 2252-2 through the conductive bumps 2230-2. Each of the light emitting devices 2220-3 of the present embodiment has a first electrode 2226-3 and a second electrode 2228-3 on the top portion 2222-3, and the first electrode 2226-3 and the second electrode 2228-3 are respectively and electrically connected to the corresponding first circuit layer 2252-3 through the conductive bumps 2230-3.

FIG. 32 illustrates a package structure 3200 of a light emitting device according to an embodiment of the present disclosure. To facilitate description, in the following embodiments of the disclosure, the same or similar devices are denoted by similar reference numerals as those in the previous embodiments. Some devices illustrated in the previous embodiments may be omitted, and descriptions of those omitted devices can be referred to the previous embodiments, and are not repeated herein. The package structure 3200 according to the present embodiment is partially similar to the package structure 2200 according to the previous embodiment, except that the package structure 3200 further includes a heat sink 3210 disposed on the back surface 2214 of the carrier 2210 to provide the package structure 3200 superior heat dissipation effect.

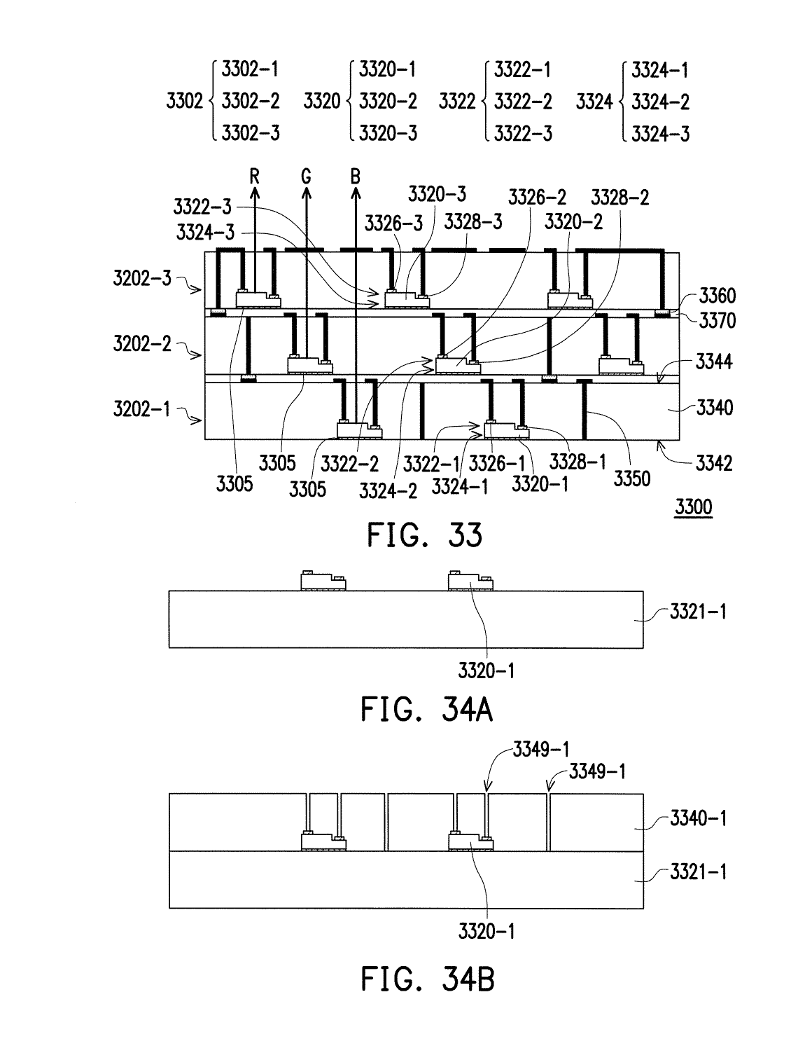

FIG. 33 illustrates a package structure 3300 of a light emitting device capable of accomplishing full-color display according to an embodiment of the present disclosure. In the present embodiments, package units having light emitting device array are formed by flip-chip bonding technique, before laminating the package units together. For example, the package units having light emitting devices in different colors such as red, green and blue, are stacked with one another to form a full-color display. Each package unit has an interconnection structure itself, and the package units are electrically connected with one another through their interconnection structures. The package structure of the disclosure provides simple and quick manufacturing process and is suitable for mass production. Furthermore, solutions for optical issues such as light guiding or light mixing are also provided.

Referring to FIG. 33, the package structure 3300 of the present embodiment includes plural package units 3302, plural first conductive bumps 3360 and an adhesive layer 3370. The package units 3302 are stacked with one another, and each of the package units 3302 includes an encapsulant 3340, plural light emitting devices 3320 and a circuit structure 3350. Each encapsulant 3340 has a first surface 3342 and a second surface 3344 opposite to the first surface 3342, wherein the first surface 3342 of an upper encapsulant 3340 is bonded to the second surface 3344 of a lower encapsulant 3340 of another package unit 3302. The light emitting devices 3320 are arranged in an array and embedded in the first surfaces 3342 of the corresponding encapsulants 3340. Each of the light emitting devices 3320 comprises a top portion 3322 and a bottom portion 3324 opposite to the top portion 3322, and the bottom portion 3324 of each of the light emitting devices 3320 is coplanar with the first surface 3342 of the corresponding encapsulant 3340. The circuit structure 3350 is disposed in the encapsulant 3340 or on the second surface 3344 of the encapsulant 3340. The first conductive bumps 3360 are disposed between two adjacent package units 3302 and electrically connected to the circuit structures 3350 of the two adjacent package units 3302. The adhesive layer 3370 is disposed between the two adjacent package units 3302 and encapsulating the first conductive bumps 3360.

In the present embodiment, the light emitting devices 3320 of each of the package units 3302 may be LEDs fabricated on an epitaxial substrate, and the light emitting devices 3320 of different package units 3302 emit lights in different colors.

More specifically, as shown in FIG. 33, the package structure 3300 of the present embodiment includes a first package unit 3302-1, a second package unit 3302-2 and a second package unit 3302-3 stacked with one another. The light emitting devices 3320-1 of the first package unit 3302-1 may be first color LEDs fabricated on an epitaxial substrate, for example, the LEDs emitting blue lights B upward in FIG. 22. The light emitting devices 3320-2 of the second package unit 3302-2 may be second color LEDs fabricated on an epitaxial substrate, for example, the LEDs emitting green lights G upward in FIG. 22. The light emitting devices 3320-3 of the third package unit 3302-3 may be third color LEDs fabricated on an epitaxial substrate, for example, the LEDs emitting red lights R upward in FIG. 22.

In the present embodiment, the light emitting devices 3320-1, 3320-2 and 3320-3 are horizontal-type LEDs, for example. In other words, each of the light emitting devices 3320-1 of the present embodiment has a first electrode 3326-1 and a second electrode 3328-1 on the top portion 3322-1, and the first electrode 3326-1 and the second electrode 3328-1 are respectively and electrically connected to the corresponding circuit structure 3350. In addition, the bottom portion 3324-1 of each of the light emitting devices 3320-1 is covered by an insulation layer 3305, to prevent short between the bottom portion 3324-1 of the light emitting device 3320-1 and the circuit structure 3350. Each of the light emitting devices 3320-2 of the present embodiment has a first electrode 3326-2 and a second electrode 3328-2 on the top portion 3322-2, and the first electrode 3326-2 and the second electrode 3328-2 are respectively and electrically connected to the corresponding circuit structure 3350. In addition, the bottom portion 3324-2 of each of the light emitting devices 3320-2 is covered by an insulation layer 3305, to prevent short between the bottom portion 3324-2 of the light emitting device 3320-2 and the circuit structure 3350. Each of the light emitting devices 3320-3 of the present embodiment has a first electrode 3326-3 and a second electrode 3328-3 on the top portion 3322-3, and the first electrode 3326-3 and the second electrode 3328-3 are respectively and electrically connected to the corresponding circuit structure 3350. In addition, the bottom portion 3324-3 of each of the light emitting devices 3320-3 is covered by an insulation layer 3305, to prevent short between the bottom portion 3324-3 of the light emitting device 3320-3 and the circuit structure 3350.

In the present embodiment, the insulation layer 3305 may be formed by addition process, or may be formed an undoped layer formed in the epitaxial process of the light emitting devices 3320-1, 3320-2 and 3320-3.

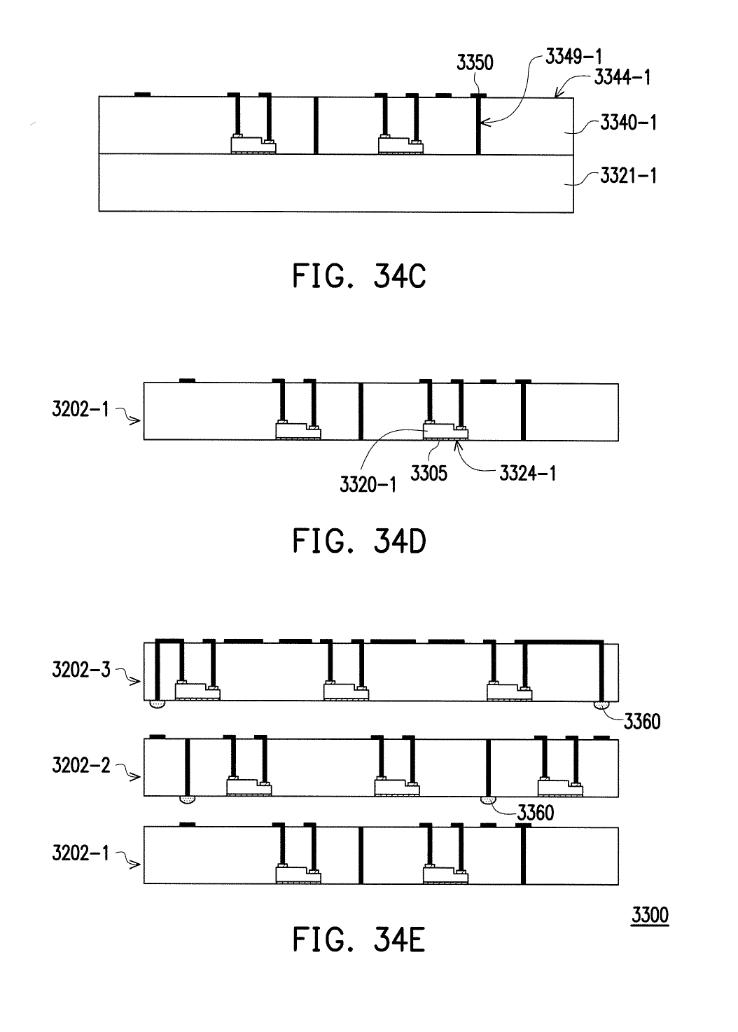

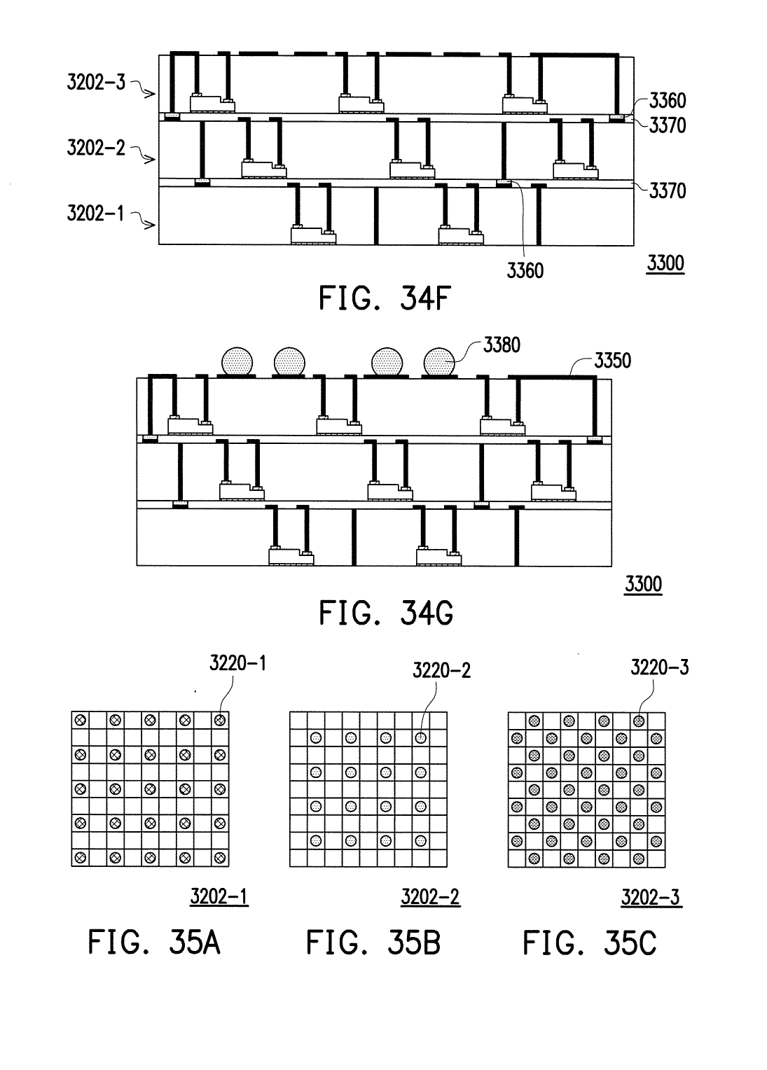

FIG. 34A through FIG. 34G illustrate a package process of the package structure 3300 of FIG. 33. Firstly, as shown in FIG. 34A, an epitaxial substrate 3321-1 is provided, and plural light emitting devices 3320-1 are formed on the epitaxial substrate 3321-1 by performing an epitaxial process. Then, as shown in FIG. 34B, a non-conductive layer covering the epitaxial substrate 3321-1 is provided to form an encapsulant 3340-1, and through holes 3349-1 are formed in the encapsulant 3340-1 by removing a part of the encapsulant 3340-1 through laser or etching. Each of the through holes 3349-1 may expose a portion of the corresponding light emitting device 3320-1, or pass through the encapsulant 3340-1. Herein, the non-conductive layer may be a non-conductive film, an underfill or a UV adhesive.

Then, as shown in FIG. 34C, conductive material such as copper is filled into the through holes 3349-1, and circuits are fabricated on the second surface 3344-1 of the encapsulant 3340-1, to form a circuit structure 3350. Then, as shown in FIG. 34D, the epitaxial substrate 3321-1 is removed by lift-off technique, and an insulation layer 3305 can be selectively formed on the bottom portion 3324-1 of each of the light emitting devices 3320-1. Here, the first package unit 3302-1 in the lower layer is formed.

Next, as shown in FIG. 34E, the steps as shown in FIG. 34A through FIG. 34D are repeated to form a second package unit 3302-2 and a third package unit 3302-3. And, first conductive bumps 3360 are formed on the first package unit 3302-1, the second package unit 3302-2 and the third package unit 3302-3. Then, as shown in FIG. 34F, the first package unit 3302-1, the second package unit 3302-2 and the third package unit 3302-3 are stacked and electrically connected with one another through the first conductive bumps 3360. And, adhesive layers 3370 encapsulating the first conductive bumps 3360 are formed between the first package unit 3302-1 and the second package unit 3302-2 and between the second package unit 3302-2 and the third package unit 3302-3. So far, the manufacture of the package structure 3300 is substantially completed.

Furthermore, second conductive bumps 3380 electrically connected with the circuit structure 3350 for connecting the package structure 3300 to an external circuit may be formed on the top portion or the bottom portion of the packager structure 3300 as shown in FIG. 34G.

FIG. 35A through FIG. 35C respectively shows vertical projections of the light emitting devices 3320-1 of the first package unit 3302-1, the light emitting devices 3320-2 of the second package unit 3302-2 and the light emitting devices 3320-3 of the third package unit 3302-3 on a plane perpendicular to the direction of light output. As shown in FIG. 35A through FIG. 35C, the vertical projections of the light emitting devices 3320-1, 3320-2 and 3320-3 on the plane are not overlapped with one another and form an area array. Therefore, shading devices such as contacts or circuits in an upper layer are likely to block light emitted along an oblique direction from a lower light emitting device rather than light emitted along a vertical direction, and the problem of color interference is effectively eliminated.

However, in other embodiments of the disclosure, since the thin thickness (about 3 um) of the light emitting devices 3320-1, 3320-2 and 3320-3 provides merely minor influence to the light output, the light emitting devices 3320-1 of the first package unit 3302-1, the light emitting devices 3320-2 of the second package unit 3302-2 and the light emitting devices 3320-3 of the third package unit 3302-3 may be in the same layout, i.e., aligned in the vertical direction and having the vertical projections partially or completely overlapped with one another.

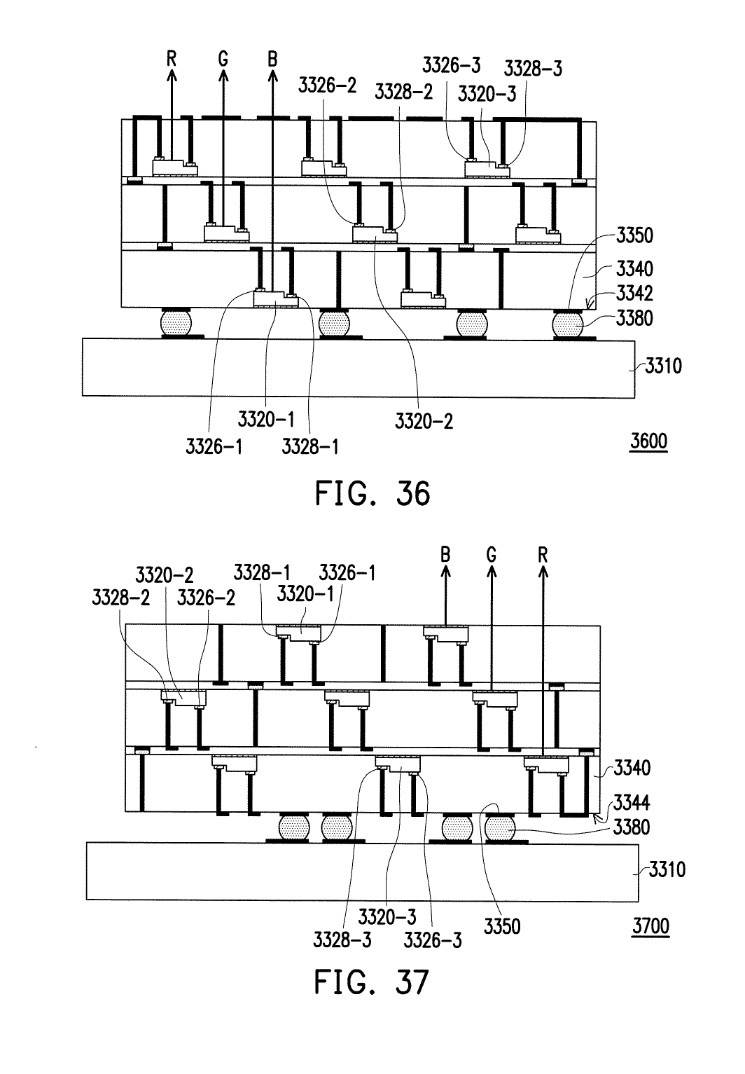

FIG. 36 illustrates a package structure 3600 of a light emitting device according to an embodiment of the present disclosure. To facilitate description, in the following embodiments of the disclosure, the same or similar devices are denoted by similar reference numerals as those in the previous embodiments. Some devices illustrated in the previous embodiments may be omitted, and descriptions of those omitted devices can be referred to the previous embodiments, and are not repeated herein. The package structure 3600 according to the present embodiment is partially similar to the package structure 3300 according to the previous embodiment, except that the package structure 3300 of the present embodiment after being completely manufactured is further bonded to a carrier through second conductive bumps 3380.

In the present embodiment, the light emitting devices 3320-1, 3320-2 and 3320-3 are top-emitting type LEDs, for example. In other words, each of the light emitting devices 3320-1 outputs light toward the first electrode 3326-1 and the second electrode 3328-1, each of the light emitting devices 3320-2 outputs light toward the first electrode 3326-2 and the second electrode 3328-2, and each of the light emitting devices 3320-3 outputs light toward the first electrode 3326-3 and the second electrode 3328-3. Therefore, the first surface 3342 of each of the encapsulants 3340 faces the carrier 3310, wherein the circuit structure 3350 of the lowermost encapsulant 3340 is electrically connected to the carrier 3310 through the second conductive bumps 3380. Herein, the carrier 3310 may be a semiconductor substrate, a glass substrate, a circuit substrate or other applicable substrates, wherein the semiconductor substrate is, for example a drive IC, including electronic circuitry.

FIG. 37 illustrates a package structure 3700 of a light emitting device according to an embodiment of the present disclosure. To facilitate description, in the following embodiments of the disclosure, the same or similar devices are denoted by similar reference numerals as those in the previous embodiments. Some devices illustrated in the previous embodiments may be omitted, and descriptions of those omitted devices can be referred to the previous embodiments, and are not repeated herein. A package structure 3700 according to the present embodiment is partially similar to the package structure 3600 according to the previous embodiment, except that light output direction of the package structure 3700 is opposite to light output direction of the package structure 3600.

More specifically, the light emitting devices 3320-1, 3320-2 and 3320-3 of the present embodiment are bottom-emitting type LEDs, for example. In other words, each of the light emitting devices 3320-1 outputs light far away from the first electrode 3326-1 and the second electrode 3328-1, each of the light emitting devices 3320-2 outputs light far away from the first electrode 3326-2 and the second electrode 3328-2, and each of the light emitting devices 3320-3 outputs light far away from the first electrode 3326-3 and the second electrode 3328-3. Therefore, the second surface 3344 of each of the encapsulants 3340 faces the carrier 3310, wherein the circuit structure 3350 of the lowermost encapsulant 3340 is electrically connected to the carrier 3310 through the second conductive bumps 3380. Herein, the carrier 3310 may be a semiconductor substrate, a glass substrate, a circuit substrate or other applicable substrates, wherein the semiconductor substrate is, for example a drive IC, including electronic circuitry.

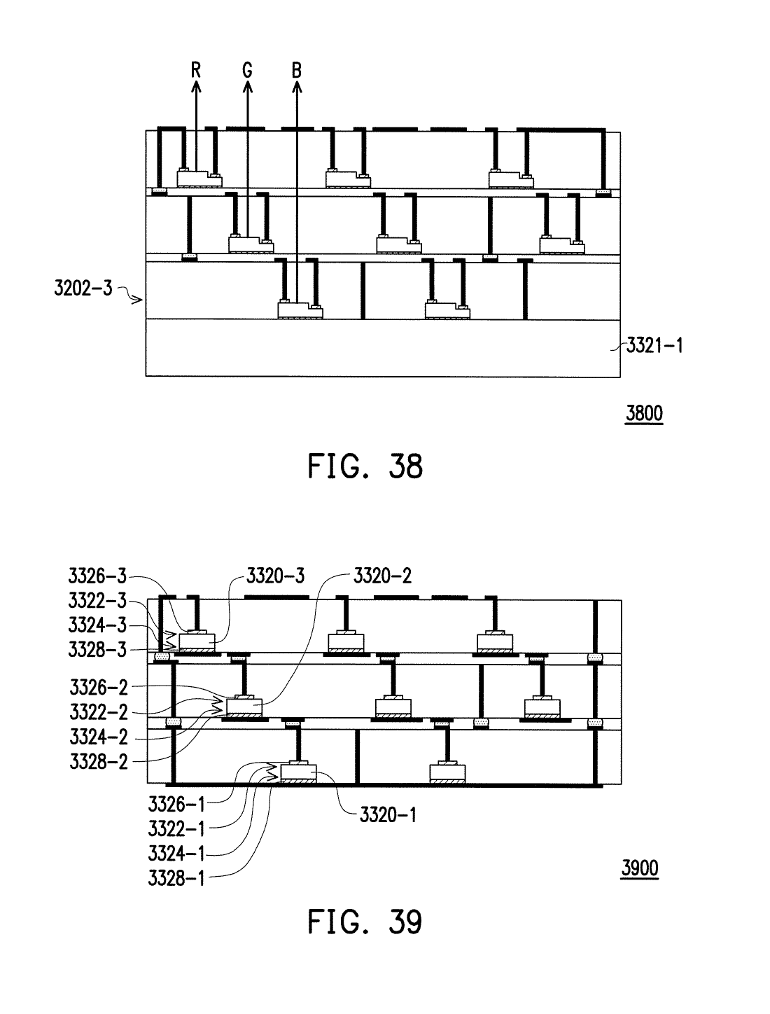

FIG. 38 illustrates a package structure 3800 of a light emitting device according to an embodiment of the present disclosure. To facilitate description, in the following embodiments of the disclosure, the same or similar devices are denoted by similar reference numerals as those in the previous embodiments. Some devices illustrated in the previous embodiments may be omitted, and descriptions of those omitted devices can be referred to the previous embodiments, and are not repeated herein. The package structure 3800 according to the present embodiment is partially similar to the package structure 3300 according to the previous embodiment, except that the epitaxial substrate 3321-1 is remained without being removed in the fabrication of the lowermost first package unit 3302-1, so as to provide a sustainable support to the structure in the following process. In addition, the epitaxial substrate 3321-1 can protect the light emitting devices 3320-1.

FIG. 39 illustrates a package structure 3900 of a light emitting device according to an embodiment of the present disclosure. In the present embodiment, the same or similar devices are denoted by similar reference numerals as those in the previous embodiments. Some devices illustrated in the previous embodiments may be omitted, and descriptions of those omitted devices can be referred to the previous embodiments. Main difference between the present embodiment and the previous embodiment is illustrated below. The package structure 3900 according to the present embodiment is partially similar to the package structure 3300 according to the previous embodiment, except that the light emitting devices 3320-1, 3320-2 and 3320-3 are vertical-type LEDs.

More specifically, each of the light emitting device 3320-1 includes a first electrode 3326-1 on the top portion 3322-1 and a second electrode 3328-1 on the bottom portion 3324-1, wherein the first electrode 3326-1 may be a P-type electrode of LED, and the second electrode 3328-1 may be an N-type electrode of LED. Each of the light emitting device 3320-2 includes a first electrode 3326-2 on the top portion 3322-2 and a second electrode 3328-2 on the bottom portion 3324-2, wherein the first electrode 3326-2 may be a P-type electrode of LED, and the second electrode 3328-2 may be an N-type electrode of LED. In addition, each of the light emitting device 3320-3 includes a first electrode 3326-3 on the top portion 3322-3 and a second electrode 3328-3 on the bottom portion 3324-3, wherein the first electrode 3326-3 may be a P-type electrode of LED, and the second electrode 3328-3 may be an N-type electrode of LED.

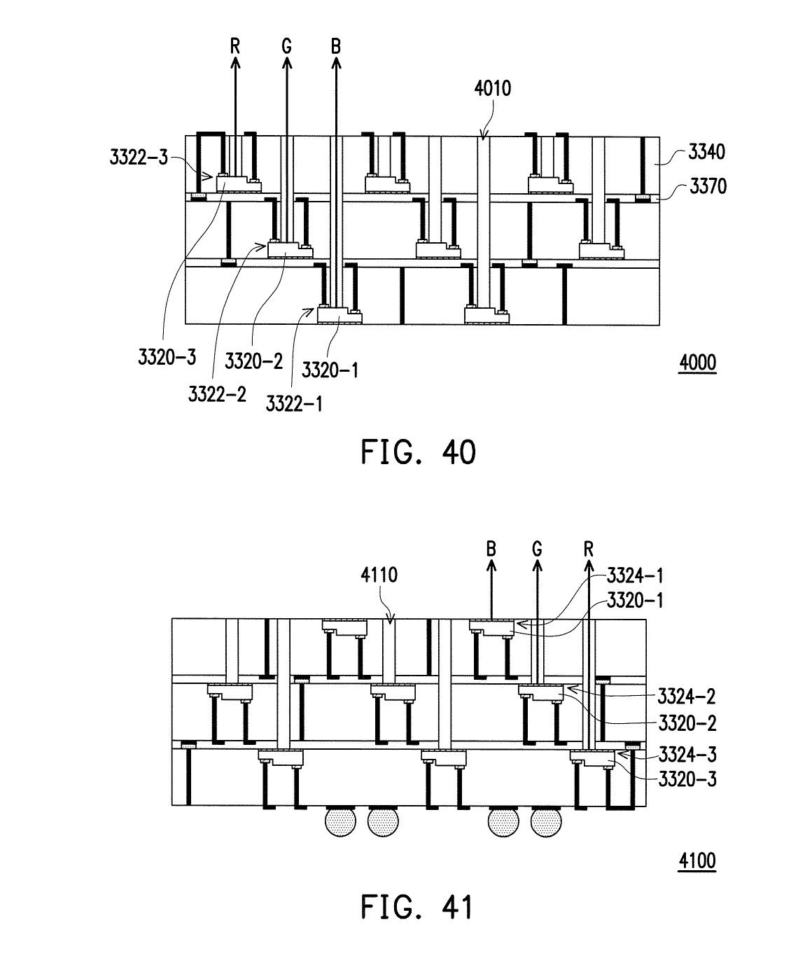

FIG. 40 illustrates a package structure 4000 of a light emitting device according to an embodiment of the present disclosure. The package structure 4000 according to the present embodiment is partially similar to the package structure 3300 according to the previous embodiment, except that the present embodiment further forms plural through holes 4010 serving as light guiding structures above the light emitting devices 3320-1, 3320-2 and 3320-3 after the package process, to achieve high light extraction efficiency. To facilitate description, in the following embodiments of the disclosure, the same or similar devices are denoted by similar reference numerals as those in the previous embodiments. Some devices illustrated in the previous embodiments may be omitted, and descriptions of those omitted devices can be referred to the previous embodiments, and are not repeated herein.

More specifically, the through holes 4010 may be formed by removing the possible encapsulant 3340 and the possible adhesive layer 3370 above the light emitting devices 3320-1, 3320-2 and 3320-3 through laser drilling, mechanical drilling or chemical etching, etc. An end of each of the through holes 4010 is connected to and exposes the top portion 3322-1 of the light emitting device 3320-1, the top portion 3322-2 of the light emitting device 3320-2 or the top portion 3322-3 of the light emitting device 3320-3, such that the blue light B emitted from the light emitting device 3320-1, the green light G emitted from the light emitting device 3320-2 or the red light R emitted from the light emitting device 3320-3 can be transmitted to the outside through the through holes 4010.

In the present embodiment, selection of the material of the encapsulant 3340 and the adhesive layer 3370 is much flexible, wherein transparent material or opaque material can be selected, because of forming the through holes 4010 in the encapsulant 3340 and the adhesive layer 3370.

FIG. 41 illustrates a package structure 4100 of a light emitting device according to an embodiment of the present disclosure. The package structure 4100 according to the present embodiment is partially similar to the package structure 4000 according to the previous embodiment, except that light output direction of the package structure 4100 is opposite to light output direction of the package structure 4000, and thus position of the through holes should be accordingly adjusted. To facilitate description, in the following embodiments of the disclosure, the same or similar devices are denoted by similar reference numerals as those in the previous embodiments. Some devices illustrated in the previous embodiments may be omitted, and descriptions of those omitted devices can be referred to the previous embodiments, and are not repeated herein.

More specifically, the through holes 4110 may be formed by removing the possible encapsulant 3340 and the possible adhesive layer 3370 above the light emitting devices 3320-2 and 3320-3 through laser drilling, mechanical drilling or chemical etching, etc. An end of each of the through holes 4110 is connected to and exposes the bottom portion 3324-2 of the light emitting device 3320-2 or the bottom portion 3324-3 of the light emitting device 3320-3, such that the green light G emitted from the light emitting device 3320-2 or the red light R emitted from the light emitting device 3320-3 can be transmitted to the outside through the through holes 4110.

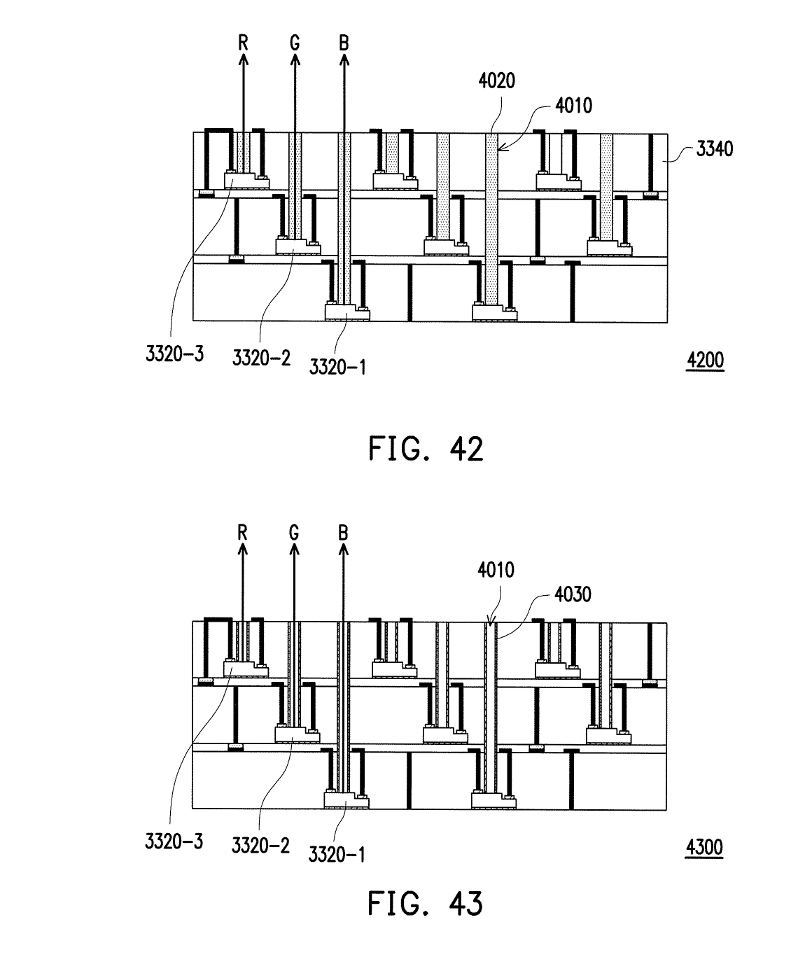

FIG. 42 illustrates a package structure 4200 of a light emitting device according to an embodiment of the present disclosure. To facilitate description, in the following embodiments of the disclosure, the same or similar devices are denoted by similar reference numerals as those in the previous embodiments. Some devices illustrated in the previous embodiments may be omitted, and descriptions of those omitted devices can be referred to the previous embodiments, and are not repeated herein. The package structure 4200 according to the present embodiment is partially similar to the package structure 4000 according to the previous embodiment, except that the present embodiment further fills transparent material 4020 with high refractive index into the through holes 4010, so as to provide optical wave guiding effect for transmitting the blue lights B emitted from the light emitting devices 3320-1, the green lights G emitted from the light emitting devices 3320-2 and the red lights R emitted from the light emitting devices 3320-3 through total reflection between the transparent material 4020 and the encapsulant 3340. Herein, the refractive index of the transparent material 4020 is greater than the refractive index of the encapsulant 3340.

Furthermore, design of the present embodiment can also be applied to the package structure 4100 of FIG. 41, wherein transparent material 4020 may be filled into the through holes 4010, to achieve similar effect.

FIG. 43 illustrates a package structure 4300 of a light emitting device according to an embodiment of the present disclosure. To facilitate description, in the following embodiments of the disclosure, the same or similar devices are denoted by similar reference numerals as those in the previous embodiments. Some devices illustrated in the previous embodiments may be omitted, and descriptions of those omitted devices can be referred to the previous embodiments, and are not repeated herein. The package structure 4300 according to the present embodiment is partially similar to the package structure 4000 according to the previous embodiment, except that inner walls of the through holes 4010 of the present embodiment are covered by a reflection material 4030 such as metal, so as to reflect the blue lights B emitted from the light emitting devices 3320-1, the green lights G emitted from the light emitting devices 3320-2, and the red lights R emitted from the light emitting devices 3320-3 in the through holes 4010.

Furthermore, design of the present embodiment can also be applied to the package structure 4100 of FIG. 41, wherein the inner walls of the through holes 4010 may be covered by reflective material 4030 such as metal, to achieve similar effect.

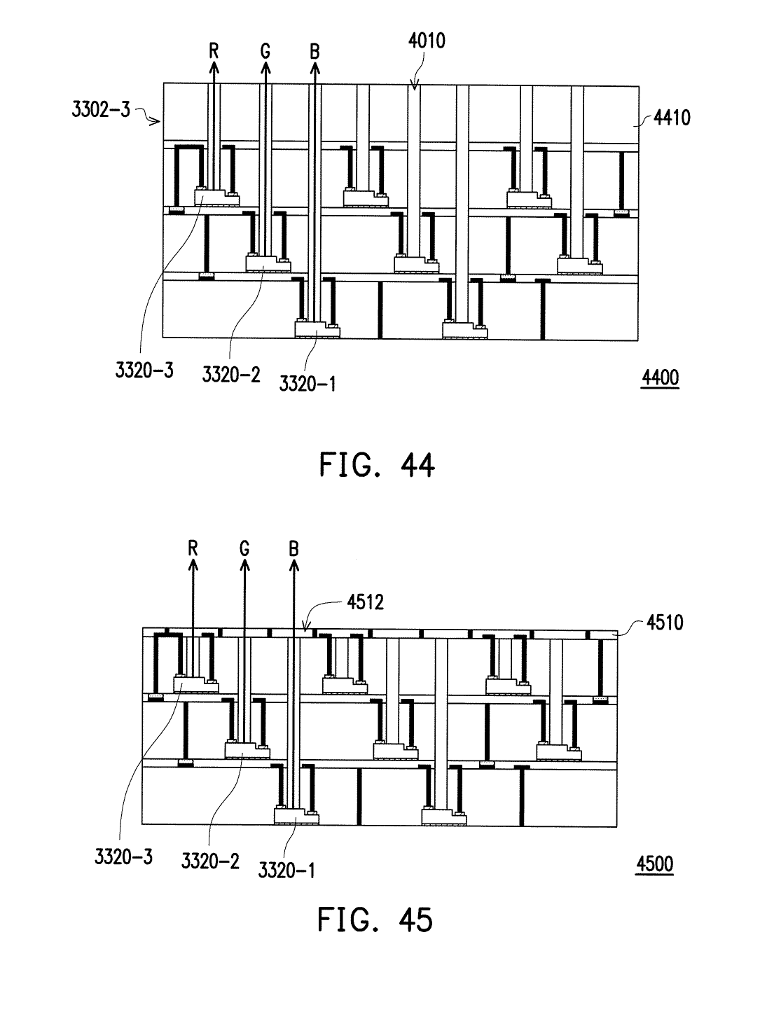

FIG. 44 illustrates a package structure 4400 of a light emitting device according to an embodiment of the present disclosure. To facilitate description, in the following embodiments of the disclosure, the same or similar devices are denoted by similar reference numerals as those in the previous embodiments. Some devices illustrated in the previous embodiments may be omitted, and descriptions of those omitted devices can be referred to the previous embodiments, and are not repeated herein. The package structure 4400 according to the present embodiment is partially similar to the package structure 4000, 4200 or 4300 according to the previous embodiments, except that a cover layer 4410 is formed over the third package unit 3302-3 in the present embodiment, and is penetrated by the light guiding structures such as through holes 4010, the transparent material 4020 (as shown in FIG. 42), the reflective material 4030 (as shown in FIG. 43). By which, lights emitted from the light emitting devices 3320-1, 3320-2 and 3320-3 converge to improve quality of light output.

FIG. 45 illustrates a package structure 4500 of a light emitting device according to an embodiment of the present disclosure. To facilitate description, in the following embodiments of the disclosure, the same or similar devices are denoted by similar reference numerals as those in the previous embodiments. Some devices illustrated in the previous embodiments may be omitted, and descriptions of those omitted devices can be referred to the previous embodiments, and are not repeated herein. The package structure 4500 according to the present embodiment is partially similar to the package structure 3300 according to the previous embodiment, except that the package structure 4500 of the present embodiment further includes a black matrix layer 4510 disposed over the third package unit 3302-3. The black matrix layer 4510 has plural transparent regions 4512 respectively corresponding to the light emitting devices 3320-1, 3320-2 and 3320-3, so as to define plural pixel regions of full color display. Herein, the black matrix layer 4510 is for example a transparent cover formed with black oblique regions thereon.

In summary, the disclosure provides various package structures of light emitting devices and manufacturing process thereof, to accomplish low temperature and fine-pitch package process, which is simple, quick and suitable for mass production. Although the aforementioned embodiments are illustrated in having two or three colors light emitting devices, in fact, the disclosure provides no restriction to the number of color of the light emitting devices. For example, four or five colors of light emitting devices may be applied in the package structure of the disclosure, to meet different requirements of light output.

Although the disclosure has been disclosed by the above embodiments, they are not intended to limit the invention. It will be apparent to one of ordinary skill in the art that modifications and variations to the disclosure may be made without departing from the spirit and scope of the disclosure. Therefore, the scope of the disclosure will be defined by the appended claims.

What is claimed is:

1. A package structure for a light emitting device, comprising:
a carrier, having a carrying surface;
a plurality of package units, stacking on the carrying surface, wherein each of the plurality of package units has a first surface and a second surface opposite the first surface and comprises:
a plurality of light emitting devices, arranged in an array and embedded in the package unit, wherein each of the plurality of light emitting devices comprises a top portion facing the carrier, a bottom portion opposite to the top portion and a first electrode on the top portion, and the bottom portion of each of the plurality of light emitting devices is coplanar with the first surface of the package unit; and
an interconnection structure, located in the plurality of package units, the interconnection structure comprising:
a plurality of conductive vias, passing through the corresponding package units and electrically connected between the corresponding first electrodes.

2. The package structure according to claim 1, wherein each of the plurality of package units further comprises:
a plurality of conductive bumps, embedded in the second surface of the package unit.

3. The package structure according to claim 2, wherein the interconnection structure further comprises:
a plurality of first circuit layers, disposed between two adjacent package units or between the carrier and the package unit adjacent to the carrier, and electrically connected to the corresponding light emitting devices.

4. The package structure according to claim 1, wherein the plurality of light emitting devices of each of the plurality of package units comprises a plurality of light emitting diodes fabricated on one epitaxial substrate.

5. The package structure according to claim 1, wherein color of lights emitted by the light emitting devices of one of the package units is different from color of lights emitted by the light emitting devices of another one of the package units.

6. The package structure according to claim 1, wherein the package units comprise a first package unit, a second package unit and a third package unit stacked with one another, the light emitting devices of the first package unit comprises a plurality of first color light emitting diodes fabricated on one epitaxial substrate, the light emitting devices of the second package unit comprises a plurality of second color light emitting diodes fabricated on another epitaxial substrate, and the light emitting devices of the third package unit comprises a plurality of third color light emitting diodes fabricated on further another epitaxial substrate.

7. The package structure according to claim 1, wherein vertical projections of the plurality of light emitting devices on the carrying surface are not overlapped with one another and form an area array.

8. The package structure according to claim 1, wherein the carrier comprises a semiconductor substrate, a glass substrate, a printed circuit board or a circuit substrate.

9. The package structure according to claim 1, further comprising a substrate, covering an exposed surface of the package units.

10. The package structure according to claim 1, further comprising a black matrix layer, disposed over the plurality of package units, wherein the black matrix layer has a plurality of transparent regions respectively corresponding to the plurality of light emitting devices.

11. The package structure according to claim 1, further comprising a plurality of light guiding structures, respectively disposed on the corresponding light emitting devices, wherein an end of each of the light guiding structures is connected to the bottom portion of the corresponding light emitting device, and each of the light guiding structures extends to an outermost surface of the package units.

12. The package structure according to claim 11, wherein each of the light guiding structures comprises a through hole filled with a transparent material, and a refractive index of the transparent material is greater than a refractive index of the package unit.

13. The package structure according to claim 12, wherein an inner wall of each of the through holes is covered by a reflection material.
